(19) United States
(12) Patent Application Publication
(10) Pub. No.: US 2026/0079203 A1
(43) Pub. Date: Mar. 19, 2026

(54) APPARATUS, SYSTEM, AND METHOD OF SYSTEM ON CHIP (SOC) FUNCTIONAL SAFETY (FUSA)

(71) Applicant: MobilEye Vision Technologies Ltd., Jerusalem (IL)

(72) Inventors: Ohad Abramzon, Ganei Tikva (IL); Oren Shalita, Tel Aviv (IL)

(73) Assignee: MobilEye Vision Technologies Ltd., Jerusalem (IL)

(21) Appl. No.: 19/287,400

(22) Filed: Jul. 31, 2025

Related U.S. Application Data
(60) Provisional application No. 63/696,806, filed on Sep. 19, 2024.

(51) Int. Cl. G01R 31/317

(52) U.S. Cl. CPC G01R 31/31717

(57) ABSTRACT

For example, a System on Chip (SoC) may include a plurality of Integrated Circuits (ICs); at least one Network on Chip (NoC) to communicate information between the plurality of ICs; and a plurality of parity circuits on a plurality of IC-NoC paths between the plurality of ICs and the at least one NoC. For example, the plurality of parity circuits may be configured according to a same parity protocol. For example, a parity circuit on an IC-NoC path between an IC and the at least one NoC may include a parity generator and a parity checker. For example, the parity generator may be configured to generate a first parity value for first information provided from the IC to the at least one NoC, and the parity checker may be configured to check a second parity value of second information provided from the at least one NoC to the IC.

### CROSS-REFERENCE

This application claims the benefit of and priority from U.S. Provisional Patent Application No. 63/696,806, entitled “APPARATUS, SYSTEM, AND METHOD OF SYSTEM ON CHIP (SOC) FUNCTIONAL SAFETY (FUSA)”, filed Sep. 19, 2024, the entire disclosure of which is incorporated herein by reference.

### BACKGROUND

Various types of devices and systems, for example, autonomous and/or robotic devices, e.g., autonomous vehicles and robots, may be configured to perform a certain functionality, e.g., autonomous driving functionalities, functionalities in a manufacturing line, and/or the like.

There may be a need to provide a technical solution to support Functional Safety (FuSA) procedures to maintain a desired FuSA level associated with the functionality of an autonomous system.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation.

Furthermore, reference numerals may be repeated among the figures to indicate corresponding or analogous elements. The figures are listed below.

FIG. 1 is a schematic block diagram illustration of a vehicle implementing a radar, in accordance with some demonstrative aspects.

FIG. 2 is a schematic block diagram illustration of a robot implementing a radar, in accordance with some demonstrative aspects.

FIG. 3 is a schematic block diagram illustration of a radar apparatus, in accordance with some demonstrative aspects.

FIG. 4 is a schematic block diagram illustration of a Frequency-Modulated Continuous Wave (FMCW) radar apparatus, in accordance with some demonstrative aspects.

FIG. 5 is a schematic illustration of an extraction scheme, which may be implemented to extract range and speed (Doppler) estimations from digital reception radar data values, in accordance with some demonstrative aspects.

FIG. 6 is a schematic illustration of an angle-determination scheme, which may be implemented to determine Angle of Arrival (AoA) information based on an incoming radio signal received by a receive antenna array, in accordance with some demonstrative aspects.

FIG. 7 is a schematic illustration of a Multiple-Input-Multiple-Output (MIMO) radar antenna scheme, which may be implemented based on a combination of Transmit (Tx) and Receive (Rx) antennas, in accordance with some demonstrative aspects.

FIG. 8 is a schematic block diagram illustration of elements of a radar device including a radar frontend and a radar processor, in accordance with some demonstrative aspects.

FIG. 9 is a schematic illustration of a radar system including a plurality of radar devices implemented in a vehicle, in accordance with some demonstrative aspects.

FIG. 10 is a schematic illustration of a System on Chip (SoC), in accordance with some demonstrative aspects.

FIG. 11 is a schematic illustration of components of a Functional Safety (FuSA) mechanism implemented by an SoC, in accordance with some demonstrative aspects.

FIG. 12 is a schematic illustration of an integrity-verification sweep scheme to implement a plurality of integrity-verification sweeps on a plurality of register files, in accordance with some demonstrative aspects.

FIG. 13 is a schematic illustration of a register file integrity verification mechanism, in accordance with some demonstrative aspects.

FIG. 14 is a schematic illustration of a state diagram of an integrity-verification sweep over a register file, in accordance with some demonstrative aspects.

FIG. 15 is a schematic illustration of a state diagram of integrity-verification trigger circuitry, in accordance with some demonstrative aspects.

FIG. 16 is a schematic illustration of components of a FuSA mechanism implemented by an SoC, in accordance with some demonstrative aspects.

FIG. 17 is a schematic illustration of a parity generator, in accordance with some demonstrative aspects.

FIG. 18 is a schematic illustration of a parity checker, in accordance with some demonstrative aspects.

FIG. 19 is a schematic illustration of Lockstep (LS) circuitry, in accordance with some demonstrative aspects.

FIG. 20 is a schematic illustration of components of a FuSA mechanism implemented by an SoC, in accordance with some demonstrative aspects.

FIG. 21 is a schematic flow chart illustration of a method of FuSA based on register file integrity verification, in accordance with some demonstrative aspects.

FIG. 22 is a schematic illustration of a product of manufacture, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

The words “exemplary” and “demonstrative” are used herein to mean “serving as an example, instance, demonstration, or illustration”. Any aspect, or design described herein as “exemplary” or “demonstrative” is not necessarily to be construed as preferred or advantageous over other aspects, or designs.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

The phrases “at least one” and “one or more” may be understood to include a numerical quantity greater than or equal to one, e.g., one, two, three, four, [ . . . ], etc. The phrase “at least one of” with regard to a group of elements may be used herein to mean at least one element from the group consisting of the elements. For example, the phrase “at least one of” with regard to a group of elements may be used herein to mean one of the listed elements, a plurality of one of the listed elements, a plurality of individual listed elements, or a plurality of a multiple of individual listed elements.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and/or may represent any information as understood in the art.

The terms “processor” or “controller” may be understood to include any kind of technological entity that allows handling of any suitable type of data and/or information. The data and/or information may be handled according to one or more specific functions executed by the processor or controller. Further, a processor or a controller may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), and the like, or any combination thereof. Any other kind of implementation of the respective functions, which will be described below in further detail, may also be understood as a processor, controller, or logic circuit. It is understood that any two (or more) processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” is understood as a computer-readable medium (e.g., a non-transitory computer-readable medium) in which data or information can be stored for retrieval. References to “memory” may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” may be used to refer to any type of executable instruction and/or logic, including firmware.

A “vehicle” may be understood to include any type of driven object. By way of example, a vehicle may be a driven object with a combustion engine, an electric engine, a reaction engine, an electrically driven object, a hybrid driven object, or a combination thereof. A vehicle may be, or may include, an automobile, a bus, a mini bus, a van, a truck, a mobile home, a vehicle trailer, a motorcycle, a bicycle, a tricycle, a train locomotive, a train wagon, a moving robot, a personal transporter, a boat, a ship, a submersible, a submarine, a drone, an aircraft, a rocket, among others.

A “ground vehicle” may be understood to include any type of vehicle, which is configured to traverse the ground, e.g., on a street, on a road, on a track, on one or more rails, off-road, or the like.

An “autonomous vehicle” may describe a vehicle capable of implementing at least one navigational change without driver input. A navigational change may describe or include a change in one or more of steering, braking, acceleration/deceleration, or any other operation relating to movement, of the vehicle. A vehicle may be described as autonomous even in case the vehicle is not fully autonomous, for example, fully operational with driver or without driver input. Autonomous vehicles may include those vehicles that can operate under driver control during certain time periods, and without driver control during other time periods. Additionally or alternatively, autonomous vehicles may include vehicles that control only some aspects of vehicle navigation, such as steering, e.g., to maintain a vehicle course between vehicle lane constraints, or some steering operations under certain circumstances, e.g., not under all circumstances, but may leave other aspects of vehicle navigation to the driver, e.g., braking or braking under certain circumstances. Additionally or alternatively, autonomous vehicles may include vehicles that share the control of one or more aspects of vehicle navigation under certain circumstances, e.g., hands-on, such as responsive to a driver input; and/or vehicles that control one or more aspects of vehicle navigation under certain circumstances, e.g., hands-off, such as independent of driver input. Additionally or alternatively, autonomous vehicles may include vehicles that control one or more aspects of vehicle navigation under certain circumstances, such as under certain environmental conditions, e.g., spatial areas, roadway conditions, or the like. In some aspects, autonomous vehicles may handle some or all aspects of braking, speed control, velocity control, steering, and/or any other additional operations, of the vehicle. An autonomous vehicle may include those vehicles that can operate without a driver. The level of autonomy of a vehicle may be described or determined by the Society of Automotive Engineers (SAE) level of the vehicle, e.g., as defined by the SAE, for example in SAE J3016 2018: Taxonomy and definitions for terms related to driving automation systems for on road motor vehicles, or by other relevant professional organizations. The SAE level may have a value ranging from a minimum level, e.g., level 0 (illustratively, substantially no driving automation), to a maximum level, e.g., level 5 (illustratively, full driving automation).

An “assisted vehicle” may describe a vehicle capable of informing a driver or occupant of the vehicle of sensed data or information derived therefrom.

The phrase “vehicle operation data” may be understood to describe any type of feature related to the operation of a vehicle. By way of example, “vehicle operation data” may describe the status of the vehicle, such as, the type of tires of the vehicle, the type of vehicle, and/or the age of the manufacturing of the vehicle. More generally, “vehicle operation data” may describe or include static features or static vehicle operation data (illustratively, features or data not changing over time). As another example, additionally or alternatively, “vehicle operation data” may describe or include features changing during the operation of the vehicle, for example, environmental conditions, such as weather conditions or road conditions during the operation of the vehicle, fuel levels, fluid levels, operational parameters of the driving source of the vehicle, or the like. More generally, “vehicle operation data” may describe or include varying features or varying vehicle operation data (illustratively, time varying features or data).

Some aspects may be used in conjunction with various devices and systems, for example, a radar sensor, a radar device, a radar system, a vehicle, a vehicular system, an autonomous vehicular system, a vehicular communication system, a vehicular device, an airborne platform, a waterborne platform, road infrastructure, sports-capture infrastructure, city monitoring infrastructure, static infrastructure platforms, indoor platforms, moving platforms, robot platforms, industrial platforms, a sensor device, a User Equipment (UE), a Mobile Device (MD), a wireless station (STA), a sensor device, a non-vehicular device, a mobile or portable device, and the like.

Some aspects may be used in conjunction with Radio Frequency (RF) systems, radar systems, vehicular radar systems, autonomous systems, robotic systems, detection systems, or the like.

Some demonstrative aspects may be used in conjunction with an RF frequency in a frequency band having a starting frequency above 10 Gigahertz (GHz), for example, a frequency band having a starting frequency between 10 GHz and 120 GHz. For example, some demonstrative aspects may be used in conjunction with an RF frequency having a starting frequency above 30 GHz, for example, above 45 GHz, e.g., above 60 GHz. For example, some demonstrative aspects may be used in conjunction with an automotive radar frequency band, e.g., a frequency band between 76 GHz and 81 GHz. However, other aspects may be implemented utilizing any other suitable frequency bands, for example, a frequency band above 140 GHz, a frequency band of 300 GHz, a sub Terahertz (THz) band, a THz band, an Infra-Red (IR) band, and/or any other frequency band.

As used herein, the term “circuitry” may refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality In some aspects, some functions associated with the circuitry may be implemented by one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g., radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and/or the like. Logic may be executed by one or more processors using memory, e.g., registers, buffers, stacks, and the like, coupled to the one or more processors, e.g., as necessary to execute the logic.

The term “communicating” as used herein with respect to a signal includes transmitting the signal and/or receiving the signal. For example, an apparatus, which is capable of communicating a signal, may include a transmitter to transmit the signal, and/or a receiver to receive the signal. The verb communicating may be used to refer to the action of transmitting or the action of receiving. In one example, the phrase “communicating a signal” may refer to the action of transmitting the signal by a transmitter, and may not necessarily include the action of receiving the signal by a receiver. In another example, the phrase “communicating a signal” may refer to the action of receiving the signal by a receiver, and may not necessarily include the action of transmitting the signal by a transmitter.

The term “antenna”, as used herein, may include any suitable configuration, structure, and/or arrangement of one or more antenna elements, components, units, assemblies, and/or arrays. In some aspects, the antenna may implement transmit and receive functionalities using separate transmit and receive antenna elements. In some aspects, the antenna may implement transmit and receive functionalities using common and/or integrated transmit/receive elements. The antenna may include, for example, a phased array antenna, a MIMO (Multiple-Input Multiple-Output) array antenna, a single element antenna, a set of switched beam antennas, and/or the like. In one example, an antenna may be implemented as a separate element or an integrated element, for example, as an on-module antenna, an on-chip antenna, or according to any other antenna architecture.

Some demonstrative aspects are described herein with respect to RF radar signals. However, other aspects may be implemented with respect to, or in conjunction with, any other radar signals, wireless signals, IR signals, acoustic signals, optical signals, wireless communication signals, communication scheme, network, standard, and/or protocol. For example, some demonstrative aspects may be implemented with respect to systems, e.g., Light Detection Ranging (LiDAR) systems, and/or sonar systems, utilizing light and/or acoustic signals.

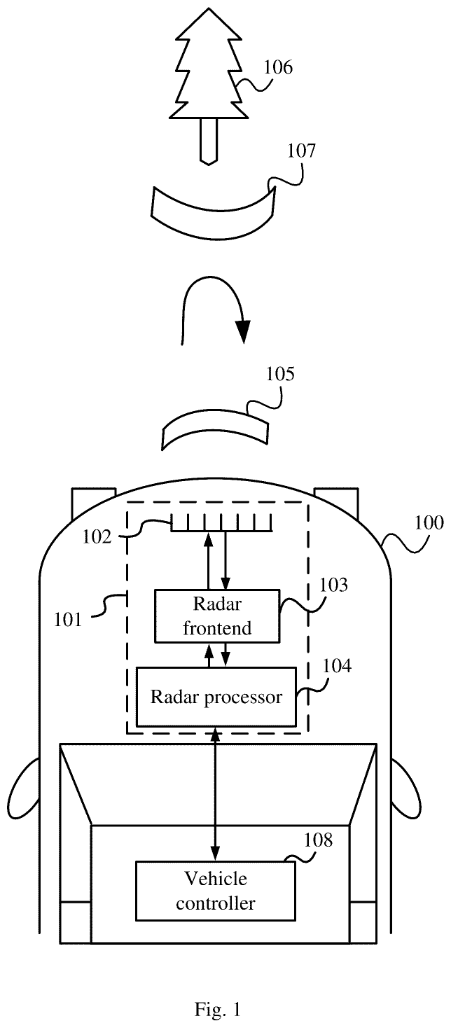

Reference is now made to FIG. 1, which schematically illustrates a block diagram of a vehicle 100 implementing a radar, in accordance with some demonstrative aspects.

In some demonstrative aspects, vehicle 100 may include a car, a truck, a motorcycle, a bus, a train, an airborne vehicle, a waterborne vehicle, a cart, a golf cart, an electric cart, a road agent, or any other vehicle.

In some demonstrative aspects, vehicle 100 may include a radar device 101, e.g., as described below. For example, radar device 101 may include a radar detecting device, a radar sensing device, a radar sensor, or the like, e.g., as described below.

In some demonstrative aspects, radar device 101 may be implemented as part of a vehicular system, for example, a system to be implemented and/or mounted in vehicle 100.

In one example, radar device 101 may be implemented as part of an autonomous vehicle system, an automated driving system, an assisted vehicle system, a driver assistance and/or support system, and/or the like.

For example, radar device 101 may be installed in vehicle 100 for detection of nearby objects, e.g., for autonomous driving.

In some demonstrative aspects, radar device 101 may be configured to detect targets in a vicinity of vehicle 100, e.g., in a far vicinity and/or a near vicinity, for example, using RF and analog chains, capacitor structures, large spiral transformers and/or any other electronic or electrical elements, e.g., as described below.

In one example, radar device 101 may be mounted onto, placed, e.g., directly, onto, or attached to, vehicle 100.

In some demonstrative aspects, vehicle 100 may include a plurality of radar aspects, vehicle 100 may include a single radar device 101.

In some demonstrative aspects, vehicle 100 may include a plurality of radar devices 101, which may be configured to cover a field of view of 360 degrees around vehicle 100.

In other aspects, vehicle 100 may include any other suitable count, arrangement, and/or configuration of radar devices and/or units, which may be suitable to cover any other field of view, e.g., a field of view of less than 360 degrees.

In some demonstrative aspects, radar device 101 may be implemented as a component in a suite of sensors used for driver assistance and/or autonomous vehicles, for example, due to the ability of radar to operate in nearly all-weather conditions.

In some demonstrative aspects, radar device 101 may be configured to support autonomous vehicle usage, e.g., as described below.

In one example, radar device 101 may determine a class, a location, an orientation, a velocity, an intention, a perceptional understanding of the environment, and/or any other information corresponding to an object in the environment.

In another example, radar device 101 may be configured to determine one or more parameters and/or information for one or more operations and/or tasks, e.g., path planning, and/or any other tasks.

In some demonstrative aspects, radar device 101 may be configured to map a scene by measuring targets' echoes (reflectivity) and discriminating them, for example, mainly in range, velocity, azimuth and/or elevation, e.g., as described below.

In some demonstrative aspects, radar device 101 may be configured to detect, and/or sense, one or more objects, which are located in a vicinity, e.g., a far vicinity and/or a near vicinity, of the vehicle 100, and to provide one or more parameters, attributes, and/or information with respect to the objects.

In some demonstrative aspects, the objects may include road users, such as other vehicles, pedestrians; road objects and markings, such as traffic signs, traffic lights, lane markings, road markings, road elements, e.g., a pavement-road meeting, a road edge, a road profile, road roughness (or smoothness); general objects, such as a hazard, e.g., a tire, a box, a crack in the road surface; and/or the like.

In some demonstrative aspects, the one or more parameters, attributes and/or information with respect to the object may include a range of the objects from the vehicle 100, an angle of the object with respect to the vehicle 100, a location of the object with respect to the vehicle 100, a relative speed of the object with respect to vehicle 100, and/or the like.

In some demonstrative aspects, radar device 101 may include a Multiple Input Multiple Output (MIMO) radar device 101, e.g., as described below.

In one example, the MIMO radar device may be configured to utilize “spatial filtering” processing, for example, beamforming and/or any other mechanism, for one or both of Transmit (Tx) signals and/or Receive (Rx) signals.

Some demonstrative aspects are described below with respect to a radar device, e.g., radar device 101, implemented as a MIMO radar. However, in other aspects, radar device 101 may be implemented as any other type of radar utilizing a plurality of antenna elements, e.g., a Single Input Multiple Output (SIMO) radar or a Multiple Input Single output (MISO) radar.

Some demonstrative aspects may be implemented with respect to a radar device, e.g., radar device 101, implemented as a MIMO radar, e.g., as described below. However, in other aspects, radar device 101 may be implemented as any other type of radar, for example, an Electronic Beam Steering radar, a Synthetic Aperture Radar (SAR), adaptive and/or cognitive radars that change their transmission according to the environment and/or ego state, a reflect array radar, or the like.

In some demonstrative aspects, radar device 101 may include an antenna arrangement 102, a radar frontend 103 configured to communicate radar signals via the antenna arrangement 102, and a radar processor 104 configured to generate radar information based on the radar signals, e.g., as described below.

In some demonstrative aspects, radar processor 104 may be configured to process radar information of radar device 101 and/or to control one or more operations of radar device 101, e.g., as described below.

In some demonstrative aspects, radar processor 104 may include, or may be implemented, partially or entirely, by circuitry and/or logic, e.g., one or more processors including circuitry and/or logic, memory circuitry and/or logic. Additionally or alternatively, one or more functionalities of radar processor 104 may be implemented by logic, which may be executed by a machine and/or one or more processors, e.g., as described below.

In one example, radar processor 104 may include at least one memory, e.g., coupled to the one or more processors, which may be configured, for example, to store, e.g., at least temporarily, at least some of the information processed by the one or more processors and/or circuitry, and/or which may be configured to store logic to be utilized by the processors and/or circuitry.

In other aspects, radar processor 104 may be implemented by one or more additional or alternative elements of vehicle 100.

In some demonstrative aspects, radar frontend 103 may include, for example, one or more (radar) transmitters, and one or more (radar) receivers, e.g., as described below.

In some demonstrative aspects, antenna arrangement 102 may include a plurality of antennas to communicate the radar signals. For example, antenna arrangement 102 may include multiple transmit antennas in the form of a transmit antenna array, and multiple receive antennas in the form of a receive antenna array. In another example, antenna arrangement 102 may include one or more antennas used both as transmit and receive antennas. In the latter case, the radar frontend 103, for example, may include a duplexer or a circulator, e.g., a circuit to separate transmitted signals from received signals.

In some demonstrative aspects, as shown in FIG. 1, the radar frontend 103 and the antenna arrangement 102 may be controlled, e.g., by radar processor 104, to transmit a radio transmit signal 105.

In some demonstrative aspects, as shown in FIG. 1, the radio transmit signal 105 may be reflected by an object 106, resulting in an echo 107.

In some demonstrative aspects, the radar device 101 may receive the echo 107, e.g., via antenna arrangement 102 and radar frontend 103, and radar processor 104 may generate radar information, for example, by calculating information about position, radial velocity (Doppler), and/or direction of the object 106, e.g., with respect to vehicle 100.

In some demonstrative aspects, radar processor 104 may be configured to provide the radar information to a vehicle controller 108 of the vehicle 100, e.g., for autonomous driving of the vehicle 100.

In some demonstrative aspects, at least part of the functionality of radar processor 104 may be implemented as part of vehicle controller 108. In other aspects, the functionality of radar processor 104 may be implemented as part of any other element of radar device 101 and/or vehicle 100. In other aspects, radar processor 104 may be implemented, as a separate part of, or as part of any other element of radar device 101 and/or vehicle 100.

In some demonstrative aspects, vehicle controller 108 may be configured to control one or more functionalities, modes of operation, components, devices, systems, and/or elements of vehicle 100.

In some demonstrative aspects, vehicle controller 108 may be configured to control one or more vehicular systems of vehicle 100, e.g., as described below.

In some demonstrative aspects, the vehicular systems may include, for example, a steering system, a braking system, a driving system, and/or any other system of the vehicle 100.

In some demonstrative aspects, vehicle controller 108 may configured to control radar device 101, and/or to process one or parameters, attributes and/or information from radar device 101.

In some demonstrative aspects, vehicle controller 108 may be configured, for example, to control the vehicular systems of the vehicle 100, for example, based on radar information from radar device 101 and/or one or more other sensors of the vehicle 100, e.g., Light Detection and Ranging (LIDAR) sensors, camera sensors, and/or the like.

In one example, vehicle controller 108 may control the steering system, the braking system, and/or any other vehicular systems of vehicle 100, for example, based on the information from radar device 101, e.g., based on one or more objects detected by radar device 101.

In other aspects, vehicle controller 108 may be configured to control any other additional or alternative functionalities of vehicle 100.

Some demonstrative aspects are described herein with respect to a radar device 101 implemented in a vehicle, e.g., vehicle 100. In other aspects a radar device, e.g., radar device 101, may be implemented as part of any other element of a traffic system or network, for example, as part of a road infrastructure, and/or any other element of a traffic network or system. Other aspects may be implemented with respect to any other system, environment, and/or apparatus, which may be implemented in any other object, environment, location, or place. For example, radar device 101 may be part of a non-vehicular device, which may be implemented, for example, in an indoor location, a stationary infrastructure outdoors, or any other location.

In some demonstrative aspects, radar device 101 may be configured to support security usage. In one example, radar device 101 may be configured to determine a nature of an operation, e.g., a human entry, an animal entry, an environmental movement, and the like, to identity a threat level of a detected event, and/or any other additional or alternative operations.

Some demonstrative aspects may be implemented with respect to any other additional or alternative devices and/or systems, for example, for a robot, e.g., as described below.

In other aspects, radar device 101 may be configured to support any other usages and/or applications.

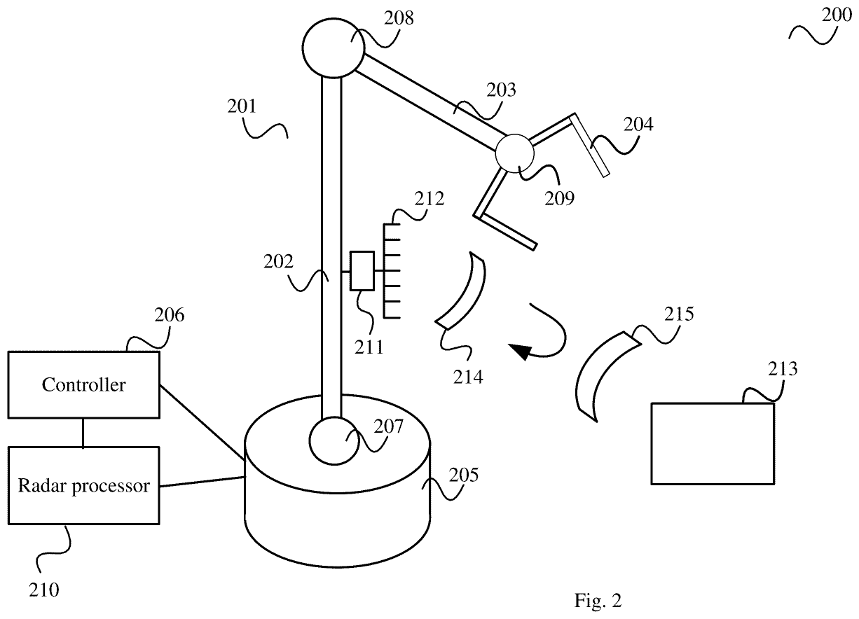

Reference is now made to FIG. 2, which schematically illustrates a block diagram of a robot 200 implementing a radar, in accordance with some demonstrative aspects.

In some demonstrative aspects, robot 200 may include a robot arm 201. The robot 200 may be implemented, for example, in a factory for handling an object 213, which may be, for example, a part that should be affixed to a product that is being manufactured. The robot arm 201 may include a plurality of movable members, for example, movable members 202, 203, 204, and a support 205. Moving the movable members 202, 203, and/or 204 of the robot arm 201, e.g., by actuation of associated motors, may allow physical interaction with the environment to carry out a task, e.g., handling the object 213.

In some demonstrative aspects, the robot arm 201 may include a plurality of joint elements, e.g., joint elements 207, 208, 209, which may connect, for example, the members 202, 203, and/or 204 with each other, and with the support 205. For example, a joint element 207, 208, 209 may have one or more joints, each of which may provide rotatable motion, e.g., rotational motion, and/or translatory motion, e.g., displacement, to associated members and/or motion of members relative to each other. The movement of the members 202, 203, 204 may be initiated by suitable actuators.

In some demonstrative aspects, the member furthest from the support 205, e.g., member 204, may also be referred to as the end-effector 204 and may include one or more tools, such as, a claw for gripping an object, a welding tool, or the like. Other members, e.g., members 202, 203, closer to the support 205, may be utilized to change the position of the end-effector 204, e.g., in three-dimensional space. For example, the robot arm 201 may be configured to function similarly to a human arm, e.g., possibly with a tool at its end.

In some demonstrative aspects, robot 200 may include a (robot) controller 206 configured to implement interaction with the environment, e.g., by controlling the robot arm's actuators, according to a control program, for example, in order to control the robot arm 201 according to the task to be performed.

In some demonstrative aspects, an actuator may include a component adapted to affect a mechanism or process in response to being driven. The actuator can respond to commands given by the controller 206 (the so-called activation) by performing mechanical movement. This means that an actuator, typically a motor (or electromechanical converter), may be configured to convert electrical energy into mechanical energy when it is activated (i.e., actuated).

In some demonstrative aspects, controller 206 may be in communication with a radar processor 210 of the robot 200.

In some demonstrative aspects, a radar fronted 211 and a radar antenna arrangement 212 may be coupled to the radar processor 210. In one example, radar fronted 211 and/or radar antenna arrangement 212 may be included, for example, as part of the robot arm 201.

In some demonstrative aspects, the radar frontend 211, the radar antenna arrangement 212 and the radar processor 210 may be operable as, and/or may be configured to form, a radar device. For example, antenna arrangement 212 may be configured to perform one or more functionalities of antenna arrangement 102 (FIG. 1), radar frontend 211 may be configured to perform one or more functionalities of radar frontend 103 (FIG. 1), and/or radar processor 210 may be configured to perform one or more functionalities of radar processor 104 (FIG. 1), e.g., as described above.

In some demonstrative aspects, for example, the radar frontend 211 and the antenna arrangement 212 may be controlled, e.g., by radar processor 210, to transmit a radio transmit signal 214.

In some demonstrative aspects, as shown in FIG. 2, the radio transmit signal 214 may be reflected by the object 213, resulting in an echo 215.

In some demonstrative aspects, the echo 215 may be received, e.g., via antenna arrangement 212 and radar frontend 211, and radar processor 210 may generate radar information, for example, by calculating information about position, speed (Doppler) and/or direction of the object 213, e.g., with respect to robot arm 201.

In some demonstrative aspects, radar processor 210 may be configured to provide the radar information to the robot controller 206 of the robot arm 201, e.g., to control robot arm 201. For example, robot controller 206 may be configured to control robot arm 201 based on the radar information, e.g., to grab the object 213 and/or to perform any other operation.

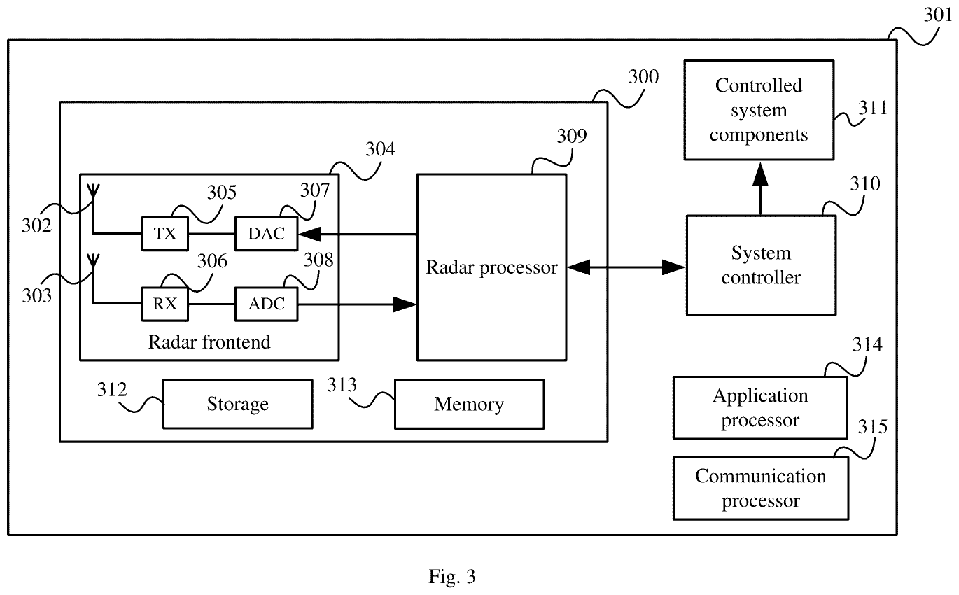

Reference is made to FIG. 3, which schematically illustrates a radar apparatus 300, in accordance with some demonstrative aspects.

In some demonstrative aspects, radar apparatus 300 may be implemented as part of a device or system 301, e.g., as described below.

For example, radar apparatus 300 may be implemented as part of, and/or may configured to perform one or more operations and/or functionalities of, the devices or systems described above with reference to FIG. 1 and/or FIG. 2. In other aspects, radar apparatus 300 may be implemented as part of any other device or system 301.

In some demonstrative aspects, radar device 300 may include an antenna arrangement, which may include one or more transmit antennas 302 and one or more receive antennas 303. In other aspects, any other antenna arrangement may be implemented.

In some demonstrative aspects, radar device 300 may include a radar frontend 304, and a radar processor 309.

In some demonstrative aspects, as shown in FIG. 3, the one or more transmit antennas 302 may be coupled with a transmitter (or transmitter arrangement) 305 of the radar frontend 304; and/or the one or more receive antennas 303 may be coupled with a receiver (or receiver arrangement) 306 of the radar frontend 304, e.g., as described below.

In some demonstrative aspects, transmitter 305 may include one or more elements, for example, an oscillator, a power amplifier and/or one or more other elements, configured to generate radio transmit signals to be transmitted by the one or more transmit antennas 302, e.g., as described below.

In some demonstrative aspects, for example, radar processor 309 may provide digital radar transmit data values to the radar frontend 304. For example, radar frontend 304 may include a Digital-to-Analog Converter (DAC) 307 to convert the digital radar transmit data values to an analog transmit signal. The transmitter 305 may convert the analog transmit signal to a radio transmit signal which is to be transmitted by transmit antennas 302.

In some demonstrative aspects, receiver 306 may include one or more elements, for example, one or more mixers, one or more filters and/or one or more other elements, configured to process, down-convert, radio signals received via the one or more receive antennas 303, e.g., as described below.

In some demonstrative aspects, for example, receiver 306 may convert a radio receive signal received via the one or more receive antennas 303 into an analog receive signal. The radar frontend 304 may include an Analog-to-Digital Converter (ADC) 308 to generate digital radar reception data values based on the analog receive signal. For example, radar frontend 304 may provide the digital radar reception data values to the radar processor 309.

In some demonstrative aspects, radar processor 309 may be configured to process the digital radar reception data values, for example, to detect one or more objects, e.g., in an environment of the device/system 301. This detection may include, for example, the determination of information including one or more of range, speed (Doppler), direction, and/or any other information, of one or more objects, e.g., with respect to the system 301.

In some demonstrative aspects, radar processor 309 may be configured to provide the determined radar information to a system controller 310 of device/system 301. For example, system controller 310 may include a vehicle controller, e.g., if device/system 301 includes a vehicular device/system, a robot controller, e.g., if device/system 301 includes a robot device/system, or any other type of controller for any other type of device/system 301.

In some demonstrative aspects, the radar information from radar processor 309 may be processed, e.g., by system controller 310 and/or any other element of system 301, for example, in combination with information from one or more other of information sources, for example, LiDAR information from a LiDAR processor, vision information from a vision-based processor, or the like.

In some demonstrative aspects, an environmental model of an environment of system 301 may be determined, e.g., by system controller 310 and/or any other element of system 301, for example, based on the radar information from radar processor 309, and/or the information from one or more other of information sources.

In some demonstrative aspects, a driving policy system, e.g., which may be implemented by system controller 310 and/or any other element of system 301, may process the environmental model, for example, to decide on one or more actions, which may be taken.

In some demonstrative aspects, system controller 310 may be configured to control one or more controlled system components 311 of the system 301, e.g., a motor, a brake, steering, and the like, e.g., by one or more corresponding actuators, for example, based on the one or more action decisions.

In some demonstrative aspects, radar device 300 may include a storage 312 or a memory 313, e.g., to store information processed by radar 300, for example, digital radar reception data values being processed by the radar processor 309, radar information generated by radar processor 309, and/or any other data to be processed by radar processor 309.

In some demonstrative aspects, device/system 301 may include, for example, an application processor 314 and/or a communication processor 315, for example, to at least partially implement one or more functionalities of system controller 310 and/or to perform communication between system controller 310, radar device 300, the controlled system components 311, and/or one or more additional elements of device/system 301.

In some demonstrative aspects, radar device 300 may be configured to generate and transmit the radio transmit signal in a form, which may support determination of range, speed, and/or direction, e.g., as described below.

For example, a radio transmit signal of a radar may be configured to include a plurality of pulses. For example, a pulse transmission may include the transmission of short high-power bursts in combination with times during which the radar device listens for echoes.

For example, in order to more optimally support a highly dynamic situation, e.g., in an automotive scenario, a continuous wave (CW) may instead be used as the radio transmit signal. However, a continuous wave, e.g., with constant frequency, may support velocity determination, but may not allow range determination, e.g., due to the lack of a time mark that could allow distance calculation.

In some demonstrative aspects, radio transmit signal 105 (FIG. 1) may be transmitted according to technologies such as, for example, Frequency-Modulated Continuous Wave (FMCW) radar, Phase-Modulated Continuous Wave (PMCW) radar, Orthogonal Frequency Division Multiplexing (OFDM) radar, and/or any other type of radar technology, which may support determination of range, velocity, and/or direction, e.g., as described below.

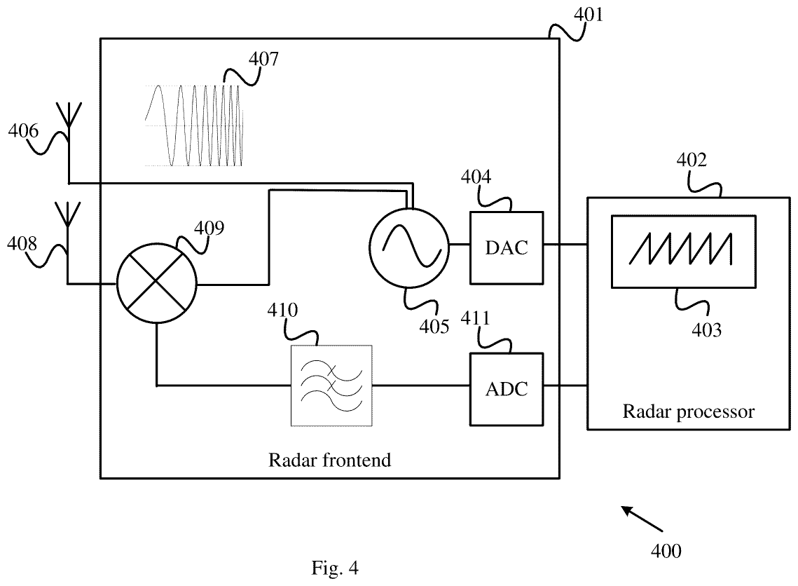

Reference is made to FIG. 4, which schematically illustrates a FMCW radar apparatus, in accordance with some demonstrative aspects.

In some demonstrative aspects, FMCW radar device 400 may include a radar frontend 401, and a radar processor 402. For example, radar frontend 304 (FIG. 3) may include one or more elements of, and/or may perform one or more operations and/or functionalities of, radar frontend 401; and/or radar processor 309 (FIG. 3) may include one or more elements of, and/or may perform one or more operations and/or functionalities of, radar processor 402.

In some demonstrative aspects, FMCW radar device 400 may be configured to communicate radio signals according to an FMCW radar technology, e.g., rather than sending a radio transmit signal with a constant frequency.

In some demonstrative aspects, radio frontend 401 may be configured to ramp up and reset the frequency of the transmit signal, e.g., periodically, for example, according to a saw tooth waveform 403. In other aspects, a triangle waveform, or any other suitable waveform may be used.

In some demonstrative aspects, for example, radar processor 402 may be configured to provide waveform 403 to frontend 401, for example, in digital form, e.g., as a sequence of digital values.

In some demonstrative aspects, radar frontend 401 may include a DAC 404 to convert waveform 403 into analog form, and to supply it to a voltage-controlled oscillator 405. For example, oscillator 405 may be configured to generate an output signal, which may be frequency-modulated in accordance with the waveform 403.

In some demonstrative aspects, oscillator 405 may be configured to generate the output signal including a radio transmit signal, which may be fed to and sent out by one or more transmit antennas 406.

In some demonstrative aspects, the radio transmit signal generated by the oscillator 405 may have the form of a sequence of chirps 407, which may be the result of the modulation of a sinusoid with the saw tooth waveform 403.

In one example, a chirp 407 may correspond to the sinusoid of the oscillator signal frequency-modulated by a “tooth” of the saw tooth waveform 403, e.g., from the minimum frequency to the maximum frequency.

In some demonstrative aspects, FMCW radar device 400 may include one or more receive antennas 408 to receive a radio receive signal. The radio receive signal may be based on the echo of the radio transmit signal, e.g., in addition to any noise, interference, or the like.

In some demonstrative aspects, radar frontend 401 may include a mixer 409 to mix the radio transmit signal with the radio receive signal into a mixed signal.

In some demonstrative aspects, radar frontend 401 may include a filter, e.g., a Low Pass Filter (LPF) 410, which may be configured to filter the mixed signal from the mixer 409 to provide a filtered signal. For example, radar frontend 401 may include an ADC 411 to convert the filtered signal into digital reception data values, which may be provided to radar processor 402. In another example, the filter 410 may be a digital filter, and the ADC 411 may be arranged between the mixer 409 and the filter 410.

In some demonstrative aspects, radar processor 402 may be configured to process the digital reception data values to provide radar information, for example, including range, speed (velocity/Doppler), and/or direction (AoA) information of one or more objects.

In some demonstrative aspects, radar processor 402 may be configured to perform a first Fast Fourier Transform (FFT) (also referred to as “range FFT”) to extract a delay response, which may be used to extract range information, and/or a second FFT (also referred to as “Doppler FFT”) to extract a Doppler shift response, which may be used to extract velocity information, from the digital reception data values.

In other aspects, any other additional or alternative methods may be utilized to extract range information. In one example, in a digital radar implementation, a correlation with the transmitted signal may be used, e.g., according to a matched filter implementation.

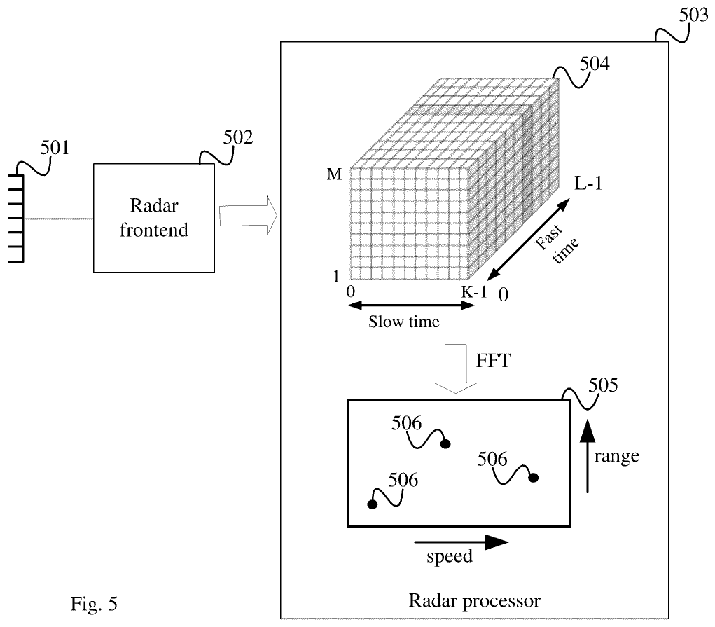

Reference is made to FIG. 5, which schematically illustrates an extraction scheme, which may be implemented to extract range and speed (Doppler) estimations from digital reception radar data values, in accordance with some demonstrative aspects. For example, radar processor 104 (FIG. 1), radar processor 210 (FIG. 2), radar processor 309 (FIG. 3), and/or radar processor 402 (FIG. 4), may be configured to extract range and/or speed (Doppler) estimations from digital reception radar data values according to one or more aspects of the extraction scheme of FIG. 5.

In some demonstrative aspects, as shown in FIG. 5, a radio receive signal, e.g., including echoes of a radio transmit signal, may be received by a receive antenna array 501. The radio receive signal may be processed by a radio radar frontend 502 to generate digital reception data values, e.g., as described above. The radio radar frontend 502 may provide the digital reception data values to a radar processor 503, which may process the digital reception data values to provide radar information, e.g., as described above.

In some demonstrative aspects, the digital reception data values may be represented in the form of a data cube 504. For example, the data cube 504 may include digitized samples of the radio receive signal, which is based on a radio signal transmitted from a transmit antenna and received by M receive antennas. In some demonstrative aspects, for example, with respect to a MIMO implementation, there may be multiple transmit antennas, and the number of samples may be multiplied accordingly.

In some demonstrative aspects, a layer of the data cube 504, for example, a horizontal layer of the data cube 504, may include samples of an antenna, e.g., a respective antenna of the M antennas.

In some demonstrative aspects, data cube 504 may include samples for K chirps. For example, as shown in FIG. 5, the samples of the chirps may be arranged in a so-called “slow time”-direction.

In some demonstrative aspects, the data cube 504 may include L samples, e.g., L=512 or any other number of samples, for a chirp, e.g., per each chirp. For example, as shown in FIG. 5, the samples per chirp may be arranged in a so-called “fast time”-direction of the data cube 504.

In some demonstrative aspects, radar processor 503 may be configured to process a plurality of samples, e.g., L samples collected for each chirp and for each antenna, by a first FFT. The first FFT may be performed, for example, for each chirp and each antenna, such that a result of the processing of the data cube 504 by the first FFT may again have three dimensions, and may have the size of the data cube 504 while including values for L range bins, e.g., instead of the values for the L sampling times.

In some demonstrative aspects, radar processor 503 may be configured to process the result of the processing of the data cube 504 by the first FFT, for example, by processing the result according to a second FFT along the chirps, e.g., for each antenna and for each range bin.

For example, the first FFT may be in the “fast time” direction, and the second FFT may be in the “slow time” direction.

In some demonstrative aspects, the result of the second FFT may provide, e.g., when aggregated over the antennas, a range/Doppler (R/D) map 505. The R/D map may have FFT peaks 506, for example, including peaks of FFT output values (in terms of absolute values) for certain range/speed combinations, e.g., for range/Doppler bins. For example, a range/Doppler bin may correspond to a range bin and a Doppler bin. For example, radar processor 503 may consider a peak as potentially corresponding to an object, e.g., of the range and speed corresponding to the peak's range bin and speed bin.

In some demonstrative aspects, the extraction scheme of FIG. 5 may be implemented for an FMCW radar, e.g., FMCW radar 400 (FIG. 4), as described above. In other aspects, the extraction scheme of FIG. 5 may be implemented for any other radar type. In one example, the radar processor 503 may be configured to determine a range/Doppler map 505 from digital reception data values of a PMCW radar, an OFDM radar, or any other radar technologies. For example, in adaptive or cognitive radar, the pulses in a frame, the waveform and/or modulation may be changed over time, e.g., according to the environment.

Referring back to FIG. 3, in some demonstrative aspects, receive antenna arrangement 303 may be implemented using a receive antenna array having a plurality of receive antennas (or receive antenna elements). For example, radar processor 309 may be configured to determine an angle of arrival of the received radio signal, e.g., echo 107 (FIG. 1) and/or echo 215 (FIG. 2). For example, radar processor 309 may be configured to determine a direction of a detected object, e.g., with respect to the device/system 301, for example, based on the angle of arrival of the received radio signal, e.g., as described below.

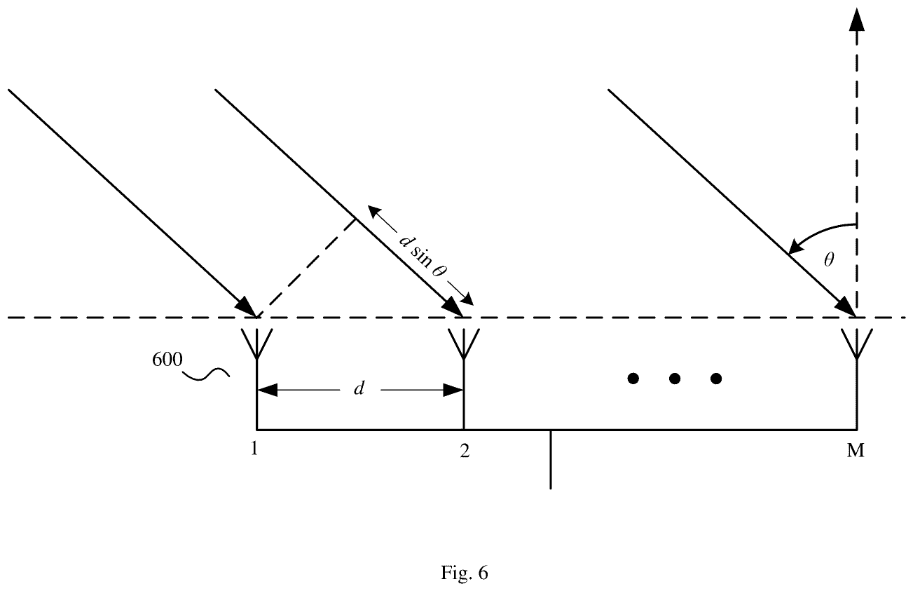

Reference is made to FIG. 6, which schematically illustrates an angle-determination scheme, which may be implemented to determine Angle of Arrival (AoA) information based on an incoming radio signal received by a receive antenna array 600, in accordance with some demonstrative aspects.

FIG. 6 depicts an angle-determination scheme based on received signals at the receive antenna array.

In some demonstrative aspects, for example, in a virtual MIMO array, the angle-determination may also be based on the signals transmitted by the array of Tx antennas.

FIG. 6 depicts a one-dimensional angle-determination scheme. Other multi-dimensional angle determination schemes, e.g., a two-dimensional scheme or a three-dimensional scheme, may be implemented.

In some demonstrative aspects, as shown in FIG. 6, the receive antenna array 600 may include M antennas (numbered, from left to right, 1 to M).

As shown by the arrows in FIG. 6, it is assumed that an echo is coming from an object located at the top left direction. Accordingly, the direction of the echo, e.g., the incoming radio signal, may be towards the bottom right. According to this example, the further to the left a receive antenna is located, the earlier it will receive a certain phase of the incoming radio signal.

For example, a phase difference, denoted Δφ, between two antennas of the receive antenna array 600 may be determined, e.g., as follows:

$$Δφ = \frac{2 π}{λ} \cdot d \cdot sin ( θ )$$

wherein λ denotes a wavelength of the incoming radio signal, d denotes a distance between the two antennas, and θ denotes an angle of arrival of the incoming radio signal, e.g., with respect to a normal direction of the array.

In some demonstrative aspects, radar processor 309 (FIG. 3) may be configured to utilize this relationship between phase and angle of the incoming radio signal, for example, to determine the angle of arrival of echoes, for example by performing an FFT, e.g., a third FFT (“angular FFT”) over the antennas.

In some demonstrative aspects, multiple transmit antennas, e.g., in the form of an antenna array having multiple transmit antennas, may be used, for example, to increase the spatial resolution, e.g., to provide high-resolution radar information. For example, a MIMO radar device may utilize a virtual MIMO radar antenna, which may be formed as a convolution of a plurality of transmit antennas convolved with a plurality of receive antennas.

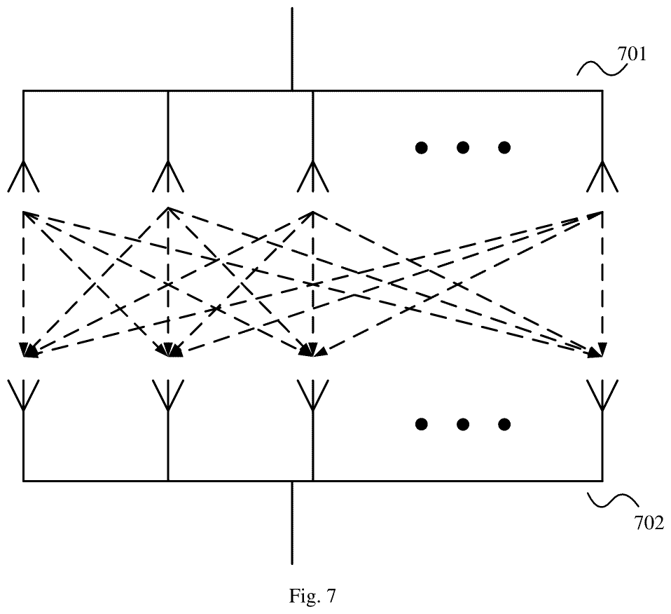

Reference is made to FIG. 7, which schematically illustrates a MIMO radar antenna scheme, which may be implemented based on a combination of Transmit (Tx) and Receive (Rx) antennas, in accordance with some demonstrative aspects.

In some demonstrative aspects, as shown in FIG. 7, a radar MIMO arrangement may include a transmit antenna array 701 and a receive antenna array 702. For example, the one or more transmit antennas 302 (FIG. 3) may be implemented to include transmit antenna array 701, and/or the one or more receive antennas 303 (FIG. 3) may be implemented to include receive antenna array 702.

In some demonstrative aspects, antenna arrays including multiple antennas both for transmitting the radio transmit signals and for receiving echoes of the radio transmit signals, may be utilized to provide a plurality of virtual channels as illustrated by the dashed lines in FIG. 7. For example, a virtual channel may be formed as a convolution, for example, as a Kronecker product, between a transmit antenna and a receive antenna, e.g., representing a virtual steering vector of the MIMO radar.

In some demonstrative aspects, a transmit antenna, e.g., each transmit antenna, may be configured to send out an individual radio transmit signal, e.g., having a phase associated with the respective transmit antenna.

For example, an array of N transmit antennas and M receive antennas may be implemented to provide a virtual MIMO array of size N×M. For example, the virtual MIMO array may be formed according to the Kronecker product operation applied to the Tx and Rx steering vectors.

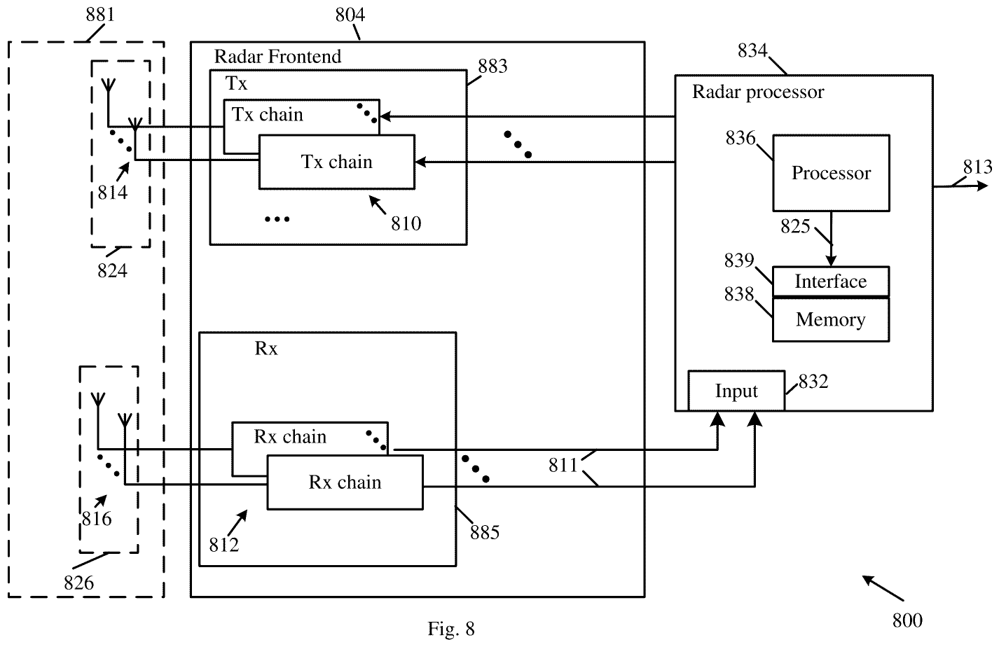

FIG. 8 is a schematic block diagram illustration of elements of a radar device 800, in accordance with some demonstrative aspects. For example, radar device 101 (FIG. 1), radar device 300 (FIG. 3), and/or radar device 400 (FIG. 4), may include one or more elements of radar device 800, and/or may perform one or more operations and/or functionalities of radar device 800.

In some demonstrative aspects, as shown in FIG. 8, radar device 800 may include a radar frontend 804 and a radar processor 834. For example, radar frontend 103 (FIG. 1), radar frontend 211 (FIG. 1), radar frontend 304 (FIG. 3), radar frontend 401 (FIG. 4), and/or radar frontend 502 (FIG. 5), may include one or more elements of radar frontend 804, and/or may perform one or more operations and/or functionalities of radar frontend 804.

In some demonstrative aspects, radar frontend 804 may be implemented as part of a MIMO radar utilizing a MIMO radar antenna 881 including a plurality of Tx antennas 814 configured to transmit a plurality of Tx RF signals (also referred to as “Tx radar signals”); and a plurality of Rx antennas 816 configured to receive a plurality of Rx RF signals (also referred to as “Rx radar signals”), for example, based on the Tx radar signals, e.g., as described below.

In some demonstrative aspects, MIMO antenna array 881, antennas 814, and/or antennas 816 may include or may be part of any type of antennas suitable for transmitting and/or receiving radar signals. For example, MIMO antenna array 881, antennas 814, and/or antennas 816, may be implemented as part of any suitable configuration, structure, and/or arrangement of one or more antenna elements, components, units, assemblies, and/or arrays. For example, MIMO antenna array 881, antennas 814, and/or antennas 816, may be implemented as part of a phased array antenna, a multiple element antenna, a set of switched beam antennas, and/or the like. In some aspects, MIMO antenna array 881, antennas 814, and/or antennas 816, may be implemented to support transmit and receive functionalities using separate transmit and receive antenna elements. In some aspects, MIMO antenna array 881, antennas 814, and/or antennas 816, may be implemented to support transmit and receive functionalities using common and/or integrated transmit/receive elements.

In some demonstrative aspects, MIMO radar antenna 881 may include a rectangular MIMO antenna array, and/or curved array, e.g., shaped to fit a vehicle design.

In other aspects, any other form, shape, and/or arrangement of MIMO radar antenna 881 may be implemented.

In some demonstrative aspects, radar frontend 804 may include one or more radios configured to generate and transmit the Tx RF signals via Tx antennas 814; and/or to process the Rx RF signals received via Rx antennas 816, e.g., as described below.

In some demonstrative aspects, radar frontend 804 may include at least one transmitter (Tx) 883 including circuitry and/or logic configured to generate and/or transmit the Tx radar signals via Tx antennas 814.

In some demonstrative aspects, radar frontend 804 may include at least one receiver (Rx) 885 including circuitry and/or logic to receive and/or process the Rx radar signals received via Rx antennas 816, for example, based on the Tx radar signals.

In some demonstrative aspects, transmitter 883, and/or receiver 885 may include circuitry; logic; Radio Frequency (RF) elements, circuitry and/or logic; baseband elements, circuitry and/or logic; modulation elements, circuitry and/or logic; demodulation elements, circuitry and/or logic; amplifiers; analog to digital and/or digital to analog converters; filters; and/or the like.

In some demonstrative aspects, transmitter 883 may include a plurality of Tx chains 810 configured to generate and transmit the Tx RF signals via Tx antennas 814, e.g., respectively; and/or receiver 885 may include a plurality of Rx chains 812 configured to receive and process the Rx RF signals received via the Rx antennas 816, e.g., respectively.

In some demonstrative aspects, radar processor 834 may be configured to generate radar information 813, for example, based on the radar signals communicated by MIMO radar antenna 881, e.g., as described below. For example, radar processor 104 (FIG. 1), radar processor 210 (FIG. 2), radar processor 309 (FIG. 3), radar processor 402 (FIG. 4), and/or radar processor 503 (FIG. 5), may include one or more elements of radar processor 834, and/or may perform one or more operations and/or functionalities of radar processor 834.

In some demonstrative aspects, radar processor 834 may be configured to generate radar information 813, for example, based on radar Rx data 811 received from the plurality of Rx chains 812. For example, radar Rx data 811 may be based on the radar Rx signals received via the Rx antennas 816.

In some demonstrative aspects, radar processor 834 may include an input 832 to receive radar input data, e.g., including the radar Rx data 811 from the plurality of Rx chains 812.

In some demonstrative aspects, radar processor 834 may include, or may be implemented, partially or entirely, by circuitry and/or logic, e.g., one or more processors including circuitry and/or logic, memory circuitry and/or logic. Additionally or alternatively, one or more functionalities of radar processor 834 may be implemented by logic, which may be executed by a machine and/or one or more processors, e.g., as described below.

In some demonstrative aspects, radar processor 834 may include at least one processor 836, which may be configured, for example, to process the radar Rx data 811, and/or to perform one or more operations, methods, and/or algorithms.

In some demonstrative aspects, radar processor 834 may include at least one memory 838, e.g., coupled to the processor 836. For example, memory 838 may be configured to store data processed by radar processor 834. For example, memory 838 may store, e.g., at least temporarily, at least some of the information processed by the processor 836, and/or logic to be utilized by the processor 836.

In some demonstrative aspects, processor 836 may interface with memory 838, for example, via a memory interface 839.

In some demonstrative aspects, processor 836 may be configured to access memory 838, e.g., to write data to memory 838 and/or to read data from memory 838, for example, via memory interface 839.

In some demonstrative aspects, memory 838 may be configured to store at least part of the radar data, e.g., some of the radar Rx data or all of the radar Rx data, for example, for processing by processor 836, e.g., as described below.

In some demonstrative aspects, memory 838 may be configured to store processed data, which may be generated by processor 836, for example, during the process of generating the radar information 813, e.g., as described below.

In some demonstrative aspects, memory 838 may be configured to store range information and/or Doppler information, which may be generated by processor 836, for example, based on the radar Rx data. In one example, the range information and/or Doppler information may be determined based on a Cross-Correlation (XCORR) operation, which may be applied to the radar Rx data. Any other additional or alternative operation, algorithm, and/or procedure may be utilized to generate the range information and/or Doppler information.

In some demonstrative aspects, memory 838 may be configured to store AoA information, which may be generated by processor 836, for example, based on the radar Rx data, the range information and/or Doppler information. In one example, the AoA information may be determined based on an AoA estimation algorithm. Any other additional or alternative operation, algorithm, and/or procedure may be utilized to generate the AoA information.

In some demonstrative aspects, radar processor 834 may be configured to generate the radar information 813 including one or more of range information, Doppler information, and/or AoA information.

In some demonstrative aspects, the radar information 813 may include Point Cloud 1 (PC1) information, for example, including raw point cloud estimations, e.g., Range, Radial Velocity, Azimuth, and/or Elevation.

In some demonstrative aspects, the radar information 813 may include additional information, which may be, for example, based on the raw point cloud estimations, and/or may be related to the raw point cloud estimations.

In some demonstrative aspects, the radar information 813 may include metadata information corresponding to the raw point cloud estimations.

In some demonstrative aspects, the radar information 813 may include, for example, information relating to a reliability level of the raw point cloud estimations, information relating to one or more parameters, conditions and/or criteria implemented in determining the raw point cloud estimations, and/or any other suitable additional or alternative information.

For example, the radar information 813 may include Log Likelihood Ratio (LLR) information corresponding to the raw point cloud estimations, Radar Cross Section (RCS) estimation information, Signal to Noise Ratio (SNR) estimation information, and/or any other suitable additional or alternative information.

In some demonstrative aspects, the radar information 813 may include Point Cloud 2 (PC2) information, which may be generated, for example, based on the PC1 information. For example, the PC2 information may include clustering information, tracking information, e.g., tracking of probabilities and/or density functions, bounding box information, classification information, orientation information, and the like. In one example, the PC2 information may be based on one or more temporal filtering techniques, which may be applied to the PC1 information, for example, for temporal filtering of multiple frames and/or multiple PC1 instances.

In some demonstrative aspects, the radar information 813 may include target tracking information corresponding to a plurality of targets in an environment of the radar device 800, e.g., as described below.

In some demonstrative aspects, radar processor 834 may be configured to generate the radar information 813 in the form of four Dimensional (4D) image information, e.g., a cube, which may represent 4D information corresponding to one or more detected targets.

In some demonstrative aspects, the 4D image information may include, for example, range values, e.g., based on the range information, velocity values, e.g., based on the Doppler information, azimuth values, e.g., based on azimuth AoA information, elevation values, e.g., based on elevation AoA information, and/or any other values.

In some demonstrative aspects, radar processor 834 may be configured to generate the radar information 813 in any other form, and/or including any other additional or alternative information.

In some demonstrative aspects, radar processor 834 may be configured to process the signals communicated via MIMO radar antenna 881 as signals of a virtual MIMO array formed by a convolution of the plurality of Rx antennas 816 and the plurality of Tx antennas 814.

In some demonstrative aspects, radar frontend 804 and/or radar processor 834 may be configured to utilize MIMO techniques, for example, to support a reduced physical array aperture, e.g., an array size, and/or utilizing a reduced number of antenna elements. For example, radar frontend 804 and/or radar processor 834 may be configured to transmit orthogonal signals via one or more Tx arrays 824 including a plurality of N elements, e.g., Tx antennas 814, and processing received signals via one or more Rx arrays 826 including a plurality of M elements, e.g., Rx antennas 816.

In some demonstrative aspects, utilizing the MIMO technique of transmission of the orthogonal signals from the Tx arrays 824 with N elements and processing the received signals in the Rx arrays 826 with M elements may be equivalent, e.g., under a far field approximation, to a radar utilizing transmission from one antenna and reception with N*M antennas. For example, radar frontend 804 and/or radar processor 834 may be configured to utilize MIMO antenna array 881 as a virtual array having an equivalent array size of N*M, which may define locations of virtual elements, for example, as a convolution of locations of physical elements, e.g., the antennas 814 and/or 816.

In some demonstrative aspects, a radar system may include a plurality of radar devices 800. For example, vehicle 100 (FIG. 1) may include a plurality of radar devices 800, e.g., as described below.

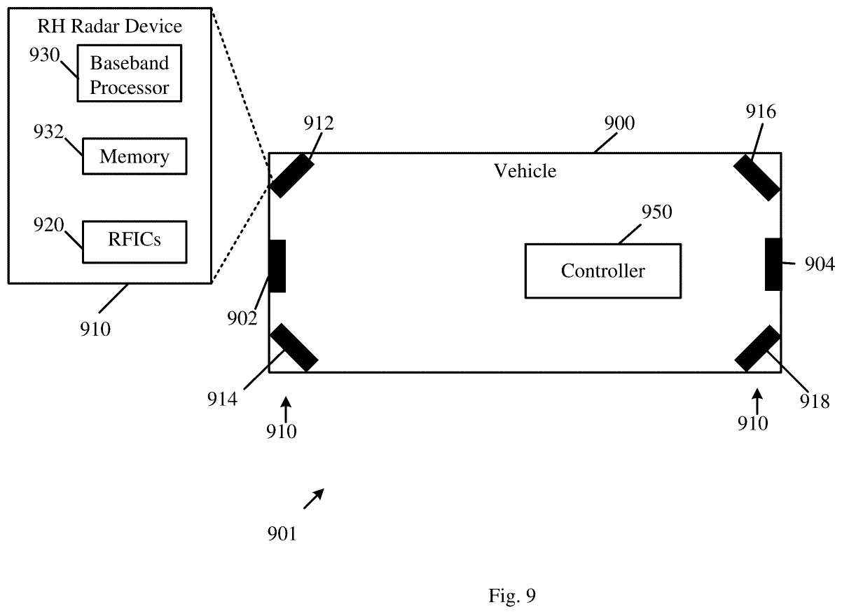

Reference is made to FIG. 9, which schematically illustrates a radar system 901 including a plurality of Radio Head (RH) radar devices (also referred to as RHs) 910 implemented in a vehicle 900, in accordance with some demonstrative aspects.

In some demonstrative aspects, as shown in FIG. 9, the plurality of RH radar devices 910 may be located, for example, at a plurality of positions around vehicle 900, for example, to provide radar sensing at a large field of view around vehicle 900, e.g., as described below.

In some demonstrative aspects, as shown in FIG. 9, the plurality of RH radar devices 910 may include, for example, six RH radar devices 910, e.g., as described below.

In some demonstrative aspects, the plurality of RH radar devices 910 may be located, for example, at a plurality of positions around vehicle 900, which may be configured to support 360-degrees radar sensing, e.g., a field of view of 360 degrees surrounding the vehicle 900, e.g., as described below.

In one example, the 360-degrees radar sensing may allow to provide a radar-based view of substantially all surroundings around vehicle 900, e.g., as described below.

In other aspects, the plurality of RH radar devices 910 may include any other number of RH radar devices 910, e.g., less than six radar devices or more than six radar devices.

In other aspects, the plurality of RH radar devices 910 may be positioned at any other locations and/or according to any other arrangement, which may support radar sensing at any other field of view around vehicle 900, e.g., 360-degrees radar sensing or radar sensing of any other field of view.

In some demonstrative aspects, as shown in FIG. 9, vehicle 900 may include a first RH radar device 902, e.g., a front RH, at a front-side of vehicle 900.

In some demonstrative aspects, as shown in FIG. 9, vehicle 900 may include a second RH radar device 904, e.g., a back RH, at a back-side of vehicle 900.

In some demonstrative aspects, as shown in FIG. 9, vehicle 900 may include one or more of RH radar devices at one or more respective corners of vehicle 900. For example, vehicle 900 may include a first corner RH radar device 912 at a first corner of vehicle 900, a second corner RH radar device 914 at a second corner of vehicle 900, a third corner RH radar device 916 at a third corner of vehicle 900, and/or a fourth corner RH radar device 918 at a fourth corner of vehicle 900.

In some demonstrative aspects, vehicle 900 may include one, some, or all, of the plurality of RH radar devices 910 shown in FIG. 9. For example, vehicle 900 may include the front RH radar device 902 and/or back RH radar device 904.

In other aspects, vehicle 900 may include any other additional or alternative radar devices, for example, at any other additional or alternative positions around vehicle 900. In one example, vehicle 900 may include a side radar, e.g., on a side of vehicle 900.

In some demonstrative aspects, as shown in FIG. 9, vehicle 900 may include a radar system controller 950 configured to control one or more, e.g., some or all, of the RH radar devices 910.

In some demonstrative aspects, at least part of the functionality of radar system controller 950 may be implemented by a dedicated controller, e.g., a dedicated system controller or central controller, which may be separate from the RH radar devices 910, and may be configured to control some or all of the RH radar devices 910.

In some demonstrative aspects, at least part of the functionality of radar system controller 950 may be implemented as part of at least one RH radar device 910.

In some demonstrative aspects, at least part of the functionality of radar system controller 950 may be implemented by a radar processor of an RH radar device 910. For example, radar processor 834 (FIG. 8) may include one or more elements of radar system controller 950, and/or may perform one or more operations and/or functionalities of radar system controller 950.

In some demonstrative aspects, at least part of the functionality of radar system controller 950 may be implemented by a system controller of vehicle 900. For example, vehicle controller 108 (FIG. 1) may include one or more elements of radar system controller 950, and/or may perform one or more operations and/or functionalities of radar system controller 950.

In other aspects, one or more functionalities of system controller 950 may be implemented as part of any other element of vehicle 900.

In some demonstrative aspects, as shown in FIG. 9, an RH radar device 910 of the plurality of RH radar devices 910, may include a baseband processor 930 (also referred to as a “Baseband Processing Unit (BPU)”), which may be configured to control communication of radar signals by the RH radar device 910, and/or to process radar signals communicated by the RH radar device 910. For example, baseband processor 930 may include one or more elements of radar processor 834 (FIG. 8), and/or may perform one or more operations and/or functionalities of radar processor 834 (FIG. 8).

In other aspects, an RH radar device 910 of the plurality of RH radar devices 910 may exclude one or more, e.g., some or all, functionalities of baseband processor 930. For example, controller 950 may be configured to perform one or more, e.g., some or all, functionalities of the baseband processor 930 for the RH.

In one example, controller 950 may be configured to perform baseband processing for all RH radar devices 910, and all RH radio devices 910 may be implemented without baseband processors 930.

In another example, controller 950 may be configured to perform baseband processing for one or more first RH radar devices 910, and the one or more first RH radio devices 910 may be implemented without baseband processors 930; and/or one or more second RH radar devices 910 may be implemented with one or more functionalities, e.g., some or all functionalities, of baseband processors 930.

In another example, one or more, e.g., some or all, RH radar devices 910 may be implemented with one or more functionalities, e.g., partial functionalities or full functionalities, of baseband processors 930.

In some demonstrative aspects, baseband processor 930 may include one or more components and/or elements configured for digital processing of radar signals communicated by the RH radar device 910, e.g., as described below.

In some demonstrative aspects, baseband processor 930 may include one or more FFT engines, matrix multiplication engines, DSP processors, and/or any other additional or alternative baseband, e.g., digital, processing components.

In some demonstrative aspects, as shown in FIG. 9, RH radar device 910 may include a memory 932, which may be configured to store data processed by, and/or to be processed by, baseband processor 930. For example, memory 932 may include one or more elements of memory 838 (FIG. 8), and/or may perform one or more operations and/or functionalities of memory 838 (FIG. 8).

In some demonstrative aspects, memory 932 may include an internal memory, and/or an interface to one or more external memories, e.g., an external Double Data Rate (DDR) memory, and/or any other type of memory.

In other aspects, an RH radar device 910 of the plurality of RH radar devices 910 may exclude memory 932. For example, the RH radar device 910 may be configured to provide radar data to controller 950, e.g., in the form of raw radar data.

In some demonstrative aspects, as shown in FIG. 9, RH radar device 910 may include one or more RF units, e.g., in the form of one or more RF Integrated Chips (RFICs) 920, which may be configured to communicate radar signals, e.g., as described below.

For example, an RFIC 920 may include one or more elements of front-end 804 (FIG. 8), and/or may perform one or more operations and/or functionalities of front-end 804 (FIG. 8).

In some demonstrative aspects, the plurality of RFICs 920 may be operable to form a radar antenna array including one or more Tx antenna arrays and one or more Rx antenna arrays.

For example, the plurality of RFICs 920 may be operable to form MIMO radar antenna 881 (FIG. 8) including Tx arrays 824 (FIG. 8), and/or Rx arrays 826 (FIG. 8).

In some demonstrative aspects, a radar device, e.g., as described above with reference to FIGS. 1-9, may be configured to implement one or more operations and/or functionalities of a Functional Safety (FuSA) mechanism, which may be configured to provide a technical solution to support FuSA for a System on Chip (SoC), which may be implemented by the radar device, e.g., as described below.

For example, various systems, e.g., automotive systems in an automotive market and/or any other type of system, may implement large compute digital SoCs.

For example, these systems may be required to meet one or more FuSA requirements, e.g., industry FuSA requirements.

In one example, automotive systems may be required to meet FuSA requirements, which may be defined with respect to FuSA Automotive Safety Integrity Level (ASIL) grades.

In some demonstrative aspects, a radar device, e.g., as described above with reference to FIGS. 1-9, may be configured to implement one or more operations and/or functionalities of a FuSA mechanism, which may be configured to provide a technical solution to support FuSA ASIL grades for an SoC, e.g., as described below.

In some demonstrative aspects, the FuSA mechanism may be configured to provide a technical solution to support the FuSA ASIL grades for relatively large digital SoCs, e.g., as described below.

In one example, a large digital SoC may include a large silicon area and/or a large count of data storage circuitry, e.g., Flip-Flops.

In some demonstrative aspects, the FuSA mechanism may be configured to provide a technical solution to support the FuSA ASIL grades for the SoC with respect to permanent FuSA faults, e.g., as described below.

In some demonstrative aspects, the FuSA mechanism may be configured to provide a technical solution to support the FuSA ASIL grades for the SoC with respect to transient FuSA faults, which may occur, for example, at the Flip-Flops, e.g., as described below.

In one example, the transient FuSA faults may be a main contributor of a Failure In Time (FIT) rate of the SoC.

In some demonstrative aspects, the FuSA mechanism may be configured to provide a technical solution to support the FuSA ASIL grades with respect to the permanent FuSA faults and/or the transient FuSA faults, for example, even without significant impact of an area of the SoC, e.g., as described below.

In one example, the FuSA mechanism may be configured to provide a technical solution to support the FuSA ASIL grades for an SoC, for example, even without significant impact on SoC area, for example, compared to other FuSA methods, which may be, for example, based on Timing Data Links (TDLs), Timing Data Generators (TDGs), duplication, and/or massive Error Correction Code (ECC) protection, e.g., as described below.

In some demonstrative aspects, the FuSA mechanism may be configured to provide a technical solution to support coverage, e.g., substantially full periodic coverage, of FuSA faults, for example, including the permanent FuSA faults as well as the transient FuSA faults, which may be the main contributor to the FIT rate.

In some demonstrative aspects, in some use cases, scenarios and/or implementations there may be one or more technical problems, disadvantages, and/or inefficiencies in implementations utilizing software-based FuSA methods, which are based on software flows, for example, for complying with FuSA requirements of a large SoC. For example, the software-based FuSA methods may be configured to handle transient tests to detect transient FuSA faults.

In one example, implementation of the software-based FuSA methods for large SoC may be relatively complex, and may have a large impact in terms of time.

In another example, implementation of the software-based FuSA methods for large SoC may have a relatively high software overhead.

In another example, implementation of the software-based FuSA methods for large SoC may result in degraded performance, for example, as the software flows may not be able to run in parallel to normal operation of the SoC.

In some demonstrative aspects, an SoC may be configured to implement a FuSA mechanism, which may be configured to provide a technical solution to address one or more technical issues of one or more Hardware (HW) FuSA mechanisms for FuSA of an SoC.

For example, some HW FuSa mechanisms may focus on a key-on test for permanent FuSA fault coverage, while the transient FuSA faults may not be covered.

In one example, some HW FuSA mechanisms may toggle flops and introduce HW overhead. For example, implementation of these HW FuSA mechanisms may overstress on a functional system, which may result in faults, and/or may reduce availability of the functional system.

In another example, implementation of some HW FuSA mechanisms may increase complexity of the functional system.

In another example, many HW FuSA mechanisms may not be capable of providing a full coverage, for example, for transient FuSA faults.

In some demonstrative aspects, a radar device, e.g., as described above with reference to FIGS. 1-9, may be configured to implement one or more operations and/or functionalities of a FuSA mechanism, which may be configured to provide a technical solution to support FuSA for an SoC, for example, while avoiding overstress on a functional system of the SoC, e.g., as described below.

In some demonstrative aspects, a radar device, e.g., as described above with reference to FIGS. 1-9, may be configured to implement one or more operations and/or functionalities of a FuSA mechanism, which may be configured to provide a technical solution to support a periodic transient fault self-test for a large scale SoC, e.g., as described below.

In some demonstrative aspects, the periodic transient fault self-test may be power aware, e.g., as described below.

In some demonstrative aspects, a radar device, e.g., as described above with reference to FIGS. 1-9, may be configured to implement one or more operations and/or functionalities of a FuSA mechanism, which may be configured to provide a technical solution to support a holistic approach for self-test of an SoC, e.g., as described below.

In some demonstrative aspects, the FuSA mechanism may utilize a HW-based mechanism, which may be configured to provide a technical solution to support data management transient protection, for example, which may be aware of power and/or load, for example, on operational flows running in the background, e.g., as described below.

In some demonstrative aspects, the FuSA mechanism may be configured to provide a technical solution to support FuSA protection of the SoC, for example, even without utilizing substantially any software for FuSA management functionalities, e.g., as described below.

In some demonstrative aspects, the FuSA mechanism may be configured to provide a technical solution to support FuSA protection of the SoC, for example, while mitigating software overhead, e.g., as described below.

In some demonstrative aspects, the FuSA mechanism may be configured to provide a technical solution for FuSA protection of the SoC, for example, with high protection coverage, for example, of transient FuSA faults and/or permanent FuSA faults, e.g., as described below.

In some demonstrative aspects, the FuSA mechanism may be configured to provide a technical solution of FuSA protection of the SoC, for example, which may provide a technical solution, which may be power aware and/or performance aware solution, for example, without substantially any impact on an operation mode of the SoC, e.g., as described below.

In some demonstrative aspects, the FuSA mechanism may be configured to provide a technical solution to support FuSA protection of an SoC according to a holistic approach, which may be based on a combination of a plurality of protection mechanisms, e.g., as described below.

In some demonstrative aspects, the FuSA mechanism may implement a Network on Chip (NoC) protection mechanism, which may be configured to provide a technical solution to support an End to End (E2E) protection of data communicated over a NoC, e.g., as described below.

In some demonstrative aspects, the FuSA mechanism may implement a register protection mechanism, which may be configured to provide a technical solution to support FuSA protection for register files, e.g., configuration registers, of an SoC, for example, based on management protection of the configuration registers, e.g., as described below.

In some demonstrative aspects, the FuSA mechanism may implement a lockstep protection mechanism, e.g., as described below.

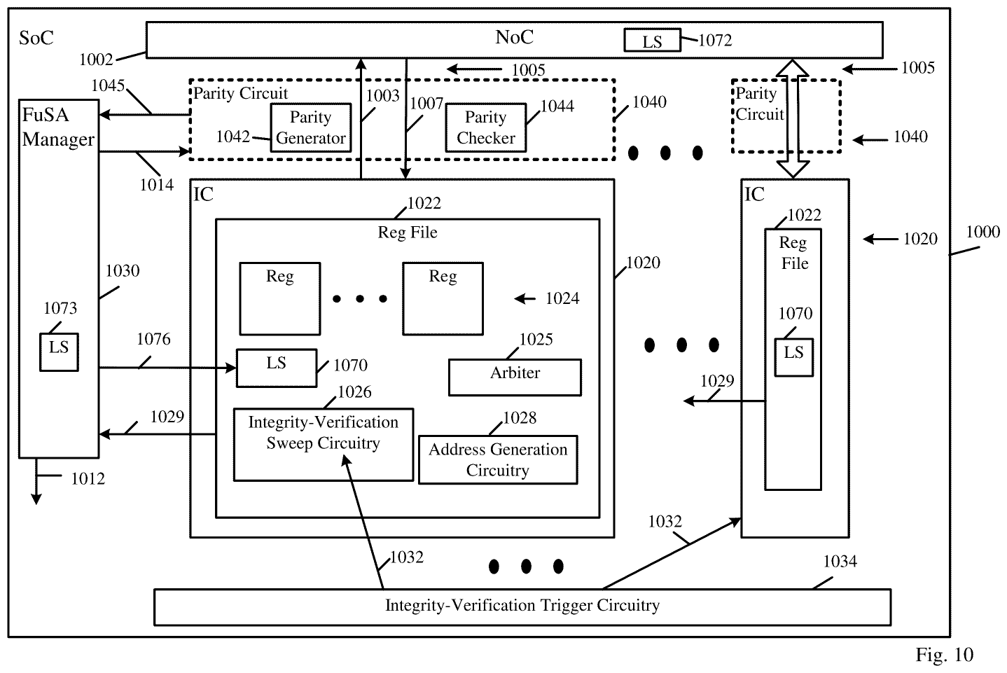

Reference is made to FIG. 10, which schematically an SoC 1000, in accordance with some demonstrative aspects.

In some demonstrative aspects, a radar device, e.g., radar device 800 (FIG. 8), and/or a radar system, e.g., system 301 (FIG. 3), may include SoC 1000, and/or may perform one or more operations and/or functionalities of SoC 1000. In one example, SoC 1000 may be configured to implement one or more elements of, and/or perform one or more operations and/or functionalities of radar processor 834 (FIG. 8) and/or radar frontend 804 (FIG. 8). In another example, SoC 1000 may be configured to implement one or more elements of, and/or perform one or more operations and/or functionalities of controller 950 (FIG. 9).

For example, SoC 1000 may be configured to control transmission of one or more radar Tx signals via Tx antennas 814 (FIG. 8), and/or to process information based on one or more radar Rx signals received via Rx antennas 816 (FIG. 8).

In some demonstrative aspects, SoC 1000 may be implemented as part of any other suitable device and/or system.

For example, SoC 1000 may be implemented as part of an industrial system, a robotic system, an autonomous system, any suitable device and/or system of process automation and/or discrete automation, e.g., mining, oil refinery, machine building, and/or energy management, and/or the like.

In one example, SoC 1000 may be implemented as part of an industrial robotic system, for example, Industrial Discrete Automation, e.g., including one or more Robot Arms, Autonomous Mobile Robots (AMRs), and/or the like.

In another example, SoC 1000 may be implemented as part of a mobile robot system, for example, an AMR, and/or the like.

In another example, SoC 1000 may be implemented as part of a control system, for example, a Distributed Control Unit (DCU) system, or the like.

In other aspects, SoC 1000 may be implemented as part of any other suitable device and/or system.

In some demonstrative aspects, SoC 1000 may include a FuSA manager 1030, which may be configured to manage FuSA for SoC 1000, e.g., as described below.

In one example, FuSA manager 1030 may be configured to perform one or more operations and/or functionalities of a FuSA mechanism, e.g., as described below.

In some demonstrative aspects, FuSA manager 1030 may be configured to generate FuSA information 1012, for example, based on one or more FuSA faults (errors) of SoC 1000, e.g., as described below.

In some demonstrative aspects, SoC 1000 may include a plurality of Integrated Circuits (ICs) 1020, e.g., as described below.

In some demonstrative aspects, the plurality of ICs 1020 may include a processor IC, e.g., as described below.

In some demonstrative aspects, the plurality of ICs 1020 may include a memory IC, e.g., as described below.

In other aspects, the plurality of ICs 1020 may include any other type of IC.

In one example, ICs 1020 may be configured to implement one or more elements of, and/or perform one or more operations and/or functionalities of radar processor 834 (FIG. 8) and/or radar frontend 804 (FIG. 8). In another example, ICs 1020 may be configured to implement one or more elements of, and/or perform one or more operations and/or functionalities of controller 950 (FIG. 9).

In some demonstrative aspects, the plurality of ICs 1020 may include one or more ICs to handle information corresponding to one or more radar Tx signals transmitted via the Tx antennas 814 (FIG. 8) and/or one or more radar Rx signals received via Rx antennas 816 (FIG. 8).

For example, ICs 1020 may be configured to control transmission of one or more radar Tx signals via Tx antennas 814 (FIG. 8), and/or to process information based on one or more radar Rx signals received via Rx antennas 816 (FIG. 8).

In some demonstrative aspects, SoC 1000 may include at least one Network on Chip (NoC) 1002, which may be configured to communicate information between the plurality of ICs 1020, e.g., as described below.

In some demonstrative aspects, SoC 1000 may be configured to implement one or more components and/or functionalities of a NoC protection mechanism, which may be configured to provide a technical solution to support an E2E protection of data communicated over the at least one NoC 1002, e.g., as described below.

In some demonstrative aspects, SoC 1000 may include a plurality of parity circuits 1040, e.g., as described below.

In some demonstrative aspects, the plurality of parity circuits 1040 may be on, e.g., arranged on, a plurality of IC-NoC paths 1005 between the plurality of ICs 1020 and the at least one NoC 1002, e.g., as described below.

In some demonstrative aspects, the plurality of parity circuits 1040 may be configured, for example, according to a same parity protocol, e.g., as described below.

In some demonstrative aspects, a parity circuit 1040 on an IC-NoC path 1005 between an IC 1020 and the at least one NoC 1002 may include a parity generator 1042 and a parity checker 1044, e.g., as described below.

In some demonstrative aspects, the parity generator 1042 may be configured to generate a first parity value for first information 1003, which may be provided from the IC 1020 to the at least one NoC 1002, e.g., as described below. For example, the first parity value may be appended to, or associated with, the first information 1003.

In some demonstrative aspects, the parity checker 1044 may be configured to check a second parity value of second information 1007, which may be provided from the at least one NoC 1002 to the IC 1020, e.g., as described below.

In some demonstrative aspects, the parity checker 1044 may be configured to selectively generate, provide, output and/or send a parity-error signal 1045, for example, based on the checking of the second parity value of second information 1007, e.g., as described below.

In some demonstrative aspects, FuSA manager 1030 may be configured to generate the FuSA information 1012, for example, based on one or more parity-error signals 1045 from the plurality of parity circuits 1040, e.g., as described below.

In some demonstrative aspects, a parity circuit 1040 may be configured to provide a parity-error signal 1045 to the FuSA manager 1030, for example, based on a parity error detected by a parity checker 1044 of the parity circuit 1040, e.g., as described below.

For example, the parity checker 1044 may be configured to detect the parity error, for example, based on a comparison between the parity value of information 1007 and a calculated parity value based on the information 1007, e.g., according to the parity protocol.

In some demonstrative aspects, the parity generator 1042 of a parity circuit 1040, e.g., of each parity circuit 1040, may be configured to generate the parity value for first information 1003, for example, according to the same parity protocol, which may be implemented by the parity generator 1044 of a parity circuit 1040, e.g., of each parity circuit 1040, for example, to check the parity value of second information 1007.

For example, the parity generator 1042 of a first parity circuit 1040 may be configured to generate the parity value for first information 1003 provided to the NoC 1002, for example, according to the same parity protocol, which may be implemented by the parity generator 1044 of a second parity circuit 1040, for example, to check the parity value of second information 1007 provided from the NoC 1002.

In some demonstrative aspects, configuring the plurality of parity circuits 1040 according to the same parity protocol may provide a technical solution to support FuSA based on an integrity check, e.g., a parity check, which may be applied to the information communicated over the at least one NoC 1002, e.g., via the IC-NoC paths 1005.

In some demonstrative aspects, the parity protocol implemented by the plurality of parity circuits 1040 may be independent of a configuration of the at least one NoC 1002, e.g., as described below.

In some demonstrative aspects, the parity protocol implemented by the plurality of parity circuits 1040 may be independent of an information format of the information communicated between the plurality of ICs 1020, e.g., as described below.

In one example, the parity protocol implemented by the plurality of parity circuits 1040 may be independent of the information format of the information 1003 and/or the information 1007.

In some demonstrative aspects, the FuSA manager 1030 may be configured to trigger a fault injection input 1014 to be provided to one or more of the plurality of parity circuits 1040, e.g., as described below.

For example, the FuSA manager 1030 may be configured to trigger the fault injection input 1014 to be provided to parity circuit 1040.

In some demonstrative aspects, the FuSA manager 1030 may be configured to trigger the fault injection input 1014 at an Always On (AON) state of the at least one NoC 1002, e.g., as described below.

In some demonstrative aspects, the parity circuit 1040 may be configured to apply the parity protocol to data communicated over the IC-NoC path 1005, e.g., as described below.

In some demonstrative aspects, the parity circuit 1040 may be configured to apply the parity protocol to address information of data packets communicated over the IC-NoC path 1005, e.g., as described below.

In some demonstrative aspects, the plurality of parity circuits 1040 may be on, e.g., arranged on, at least 50% of all IC-NoC paths 1005 between the plurality of ICs 1020 and the at least one NoC 1002, e.g., as described below.

In some demonstrative aspects, the plurality of parity circuits 1040 may be on, e.g., arranged on, at least 60% of all IC-NoC paths 1005 between the plurality of ICs 1020 and the at least one NoC 1002, e.g., as described below.

In some demonstrative aspects, the plurality of parity circuits 1040 may be on, e.g., arranged on, at least 70% of all IC-NoC paths 1005 between the plurality of ICs 1020 and the at least one NoC 1002, e.g., as described below.

In some demonstrative aspects, the plurality of parity circuits 1040 may be on, e.g., arranged on, at least 80% of all IC-NoC paths 1005 between the plurality of ICs 1020 and the at least one NoC 1002, e.g., as described below.

In some demonstrative aspects, the plurality of parity circuits 1040 may be on, e.g., arranged on, at least 90% of all IC-NoC paths 1005 between the plurality of ICs 1020 and the at least one NoC 1002, e.g., as described below.

In other aspects, the plurality of parity circuits 1040 may be on, e.g., arranged on, any other percentage, e.g., greater than 90% or less than 50%, of all IC-NoC paths 1005 between the plurality of ICs 1020 and the at least one NoC 1002.

In some demonstrative aspects, the plurality of parity circuits 1040 may be on, e.g., arranged on, at least 80% of all IC-NoC paths 1005, which have an active average utilization of at least 3%, e.g., as described below.

In some demonstrative aspects, the plurality of parity circuits 1040 may be on, e.g., arranged on, at least 80% of all IC-NoC paths 1005, which have an active average utilization of at least 4%, e.g., as described below.

In some demonstrative aspects, the plurality of parity circuits 1040 may be on, e.g., arranged on, at least 80% of all IC-NoC paths 1005, which may have an active average utilization of at least 5%, e.g., as described below.

In some demonstrative aspects, the plurality of parity circuits 1040 may be on, e.g., arranged on, at least 80% of all IC-NoC paths 1005, which may have an active average utilization of at least 10%, e.g., as described below.

In some demonstrative aspects, the plurality of parity circuits 1040 may be on, e.g., arranged on, at least 90% of all IC-NoC paths 1005, which have an active average utilization of at least 3%, e.g., as described below.

In some demonstrative aspects, the plurality of parity circuits 1040 may be on, e.g., arranged on, at least 90% of all IC-NoC paths 1005, which have an active average utilization of at least 4%, e.g., as described below.

In some demonstrative aspects, the plurality of parity circuits 1040 may be on, e.g., arranged on, at least 90% of all IC-NoC paths 1005, which have an active average utilization of at least 5%, e.g., as described below.

In some demonstrative aspects, the plurality of parity circuits 1040 may be on, e.g., arranged on, at least 90% of all IC-NoC paths 1005, which have an active average utilization of at least 10%, e.g., as described below.

In other aspects, the plurality of parity circuits 1040 may be arranged according to any other arrangement, and/or based on any other additional or alternative criteria.

In some demonstrative aspects, SoC 1000 may be configured to implement an NoC E2E data protection mechanism, which may be configured to provide a technical solution to support NoC E2E data protection of NoC 1002, e.g., as described below.

For example, the an NoC E2E data protection mechanism may be configured to provide a technical solution, which may be scalable, for example, with respect to various different NoC architectures, which may include different types of NoCs and/or different numbers of NoCs.

In some demonstrative aspects, the scalability of the NoC E2E data protection mechanism may be supported by the plurality of parity circuits 1040, which may be implemented as relatively small parity generators 1042 and/or parity checkers 1044, which may be on, e.g., arranged on, some or all of the IC-NoC paths 1005 between the plurality of ICs 1020 and the at least one NoC 1002.

In some demonstrative aspects, SoC 1000 may implement the NoC E2E data protection mechanism to provide a technical solution to support an E2E periodic fault injection, e.g., for detection of permanent FuSA faults, which may be performed, e.g., relatively easily, even during the AON state of the at least one NoC 1002.

In one example, the ability to perform the E2E periodic fault injection at the AON state of the NoC 1002 may provide a technical advantage. For example, a NoC may be the root of power up, and a smart mechanism may be required to support a “check the checker” mechanism.

In some demonstrative aspects, SoC 1000 may may implement the NoC E2E data protection mechanism to provide a technical solution to support an E2E protection of the NoC 1002, e.g., for transient FuSA faults, for example, in a scalable manner, which may support relatively large SoCs, e.g., as described below.

In some demonstrative aspects, SoC 1000 may may implement the NoC E2E data protection mechanism to provide a technical solution to support integration of full access, for example, up to a boundary of varied Intellectual Property (IP) units, e.g., implemented by ICs 1020.

In some demonstrative aspects, the IP units may include 3rd party IPs, proprietary IPs, and/or any other type of IP units.

For example, the configuration of the parity circuits 1040 according to the same parity protocol may provide a technical solution to support the NoC E2E protection of the NoC 1002, for example, in a scalable manner, which may be independent of, and/or unaffected by an architecture, a type, a size and/or a count of NoCs 1002.

For example, the configuration of the parity circuits 1040 according to the same parity protocol may provide a technical solution to support the NoC E2E protection of the NoC 1002, for example, in a scalable manner, which may be independent of, and/or unaffected by an architecture, a type, and/or a count of the IP units implemented by ICs 1020.

In some demonstrative aspects, SoC 1000 may may implement the NoC E2E data protection mechanism to provide a technical solution to support NoC E2E data protection of NoC 1002, for example, for data, address information, and/or one or more selected controls, which may be communicated over IC-NoC paths 1005, e.g., as described below.

In some demonstrative aspects, SoC 1000 may be configured to implement one or more components and/or functionalities of a register protection mechanism, which may be configured to provide a technical solution to support FuSA protection of information in a plurality of register files 1022 of the SoC 1000, e.g., as described below.

In some demonstrative aspects, an IC 1020 may include one or more register files 1022, e.g., as described below.

In some demonstrative aspects, the plurality of register files 1022 may include a plurality of static register files, e.g., as described below.

In some demonstrative aspects, the plurality of register files 1022 may include a plurality of configuration register files, e.g., as described below.

In other aspects, the plurality of register files 1022 may include any other additional and/or alternative type of registers, e.g., as described below.

In some demonstrative aspects, a register file 1022 of the plurality of register files 1022 may include integrity-verification sweep circuitry 1026, which may be configured to control an integrity-verification sweep, for example, based on a trigger signal 1032, e.g., as described below.

In some demonstrative aspects, the integrity-verification sweep may include reading a plurality of registers 1024 in the register file 1022, e.g., as described below.

In some demonstrative aspects, the integrity-verification sweep may include selectively providing a parity-error signal 1029, for example, based on parity checks of values in the plurality of registers 1024, e.g., as described below.

In some demonstrative aspects, SoC 1000 may include integrity-verification trigger circuitry 1034, which may be configured to generate a plurality of trigger signals 1032, for example, to trigger integrity-verification sweeps by the plurality of register files 1022, e.g., as described below.

In some demonstrative aspects, trigger circuitry 1034 may be configured to trigger the integrity-verification sweeps by the plurality of register files 1022, for example, according to a trigger scheme, e.g., as described below.

In some demonstrative aspects, the trigger scheme may include sequential triggering of at least some of the integrity-verification sweeps, e.g., as described below.

In other aspects, any other suitable trigger scheme may be implemented.

In some demonstrative aspects, FuSA manager 1030 may be configured to generate the FuSA information 1012, for example, based on parity-error signals 1029 from the plurality of register files 1022, e.g., as described below.

In some demonstrative aspects, the integrity-verification trigger circuitry 1034 may be configured to generate the plurality of trigger signals 1032, for example, independent from read and/or write accesses to the plurality of register files 1022, e.g., as described below.

In some demonstrative aspects, the register file 1022 may include address generation circuitry 1028, which may be configured to sequentially generate addresses of the plurality of registers 1024 in the register file 1022, for example, based on the trigger signal 1032, e.g., as described below.

In some demonstrative aspects, the register file 1022 may include an arbiter 1025, which may be configured to prioritize a read and/or write access to the register file 1022 over the integrity-verification sweep, e.g., as described below.

In some demonstrative aspects, the integrity-verification trigger circuitry 1034 may be configured to repeat generating the plurality of trigger signals 1032, for example, according to a sweep periodicity interval, e.g., as described below.

In some demonstrative aspects, the sweep periodicity interval may be shorter than a Fault Tolerant Time Interval (FTTI) for the SoC 1000, e.g., as described below.

In other aspects, any other sweep periodicity interval may be implemented.

In some demonstrative aspects, the trigger scheme may be configured to trigger staggered execution of the at least some of the integrity-verification sweeps, e.g., as described below.

In some demonstrative aspects, the trigger scheme may include sequential triggering of at least 50% of the integrity-verification sweeps, e.g., as described below.

In some demonstrative aspects, the trigger scheme may include sequential triggering of at least 60% of the integrity-verification sweeps, e.g., as described below.

In some demonstrative aspects, the trigger scheme may include sequential triggering of at least 70% of the integrity-verification sweeps, e.g., as described below.

In some demonstrative aspects, the trigger scheme may include sequential triggering of at least 80% of the integrity-verification sweeps, e.g., as described below.

In some demonstrative aspects, the trigger scheme may include sequential triggering of at least 90% of the integrity-verification sweeps, e.g., as described below.

In other aspects, any other suitable trigger scheme, e.g., including sequential triggering of two or more integrity-verification sweeps, non-sequential triggering of two or more integrity-verification sweeps, staggered triggering of two or more integrity-verification sweeps, and/or non-staggered triggering of two or more integrity-verification sweeps, may be implemented.

In some demonstrative aspects, SoC 1000 may be configured to implement the register protection mechanism, for example, to support FuSA protection on configuration registers 1024 in a register file 1022, which may be critical for operation of SoC 1000. For example, the FuSA protection may cover many flip-flops and logic, e.g., top logic.

In one example, components of the register protection mechanism, e.g., the integrity-verification sweep circuitry 1026, the address generation circuitry 1029, and/or the arbiter 1025, may be selectively included in one or more register files 1022, which may be more important for FuSA protection, for example, configuration registers, and/or static registers.

In some demonstrative aspects, integrity-verification sweep circuitry 1026 may be configured to trigger an integrity check of a register 1024, for example, by suitable parity check circuitry and/or any other suitable integrity-check logic.

For example, integrity-verification sweep circuitry 1026 may be configured to trigger an integrity check of a register 1024 by triggering a read operation to read from the register 1024. For example, the integrity check, e.g., the parity check, may be performed on the information read from the register 1024.

In some demonstrative aspects, SoC 1000 may implement the register protection mechanism to provide a technical solution to support FuSA protection for configuration registers 1024, for example, by confirming a validity of check bits in configuration registers 1024, for example, during an operational mode of IC 1020.

In some demonstrative aspects, SoC 1000 may implement the register protection mechanism to provide a technical solution to support FuSA protection for content, e.g., data, address, and/or control content, of the register files 1022, e.g., in the register configuration structure.

In some demonstrative aspects, SoC 1000 may implement the register protection mechanism to provide a technical solution to perform periodic continuous integrity check of the register files 1022 by hardware blocks, e.g., the integrity-verification sweep circuitry 1026, the address generation circuitry 1029, and/or the arbiter 1025, which may be operated, for example, even without software intervention.

For example, the implementation of the hardware blocks may provide a technical solution to support a periodic continuous integrity check of the register files 1022, for example, with a reduced periodicity, e.g., under the FTTI for the SoC 1000.

In some demonstrative aspects, SoC 1000 may implement the register protection mechanism to provide a technical solution to support full coverage for on-going flips of register files 1022.

In some demonstrative aspects, SoC 1000 may implement the register protection mechanism to provide a technical solution to support integrity verification of the register files 1022, for example, even during a mission mode of the SoC 1000.

For example, the register protection mechanism, e.g., including the integrity-verification sweep circuitry 1026, the address generation circuitry 1029, and/or the arbiter 1025, may be configured to provide a technical solution to support priority of the mission mode of the SoC 1000, e.g., over the integrity-verification sweep, e.g., as described below.

In some demonstrative aspects, the register protection mechanism, e.g., including the integrity-verification sweep circuitry 1026, the address generation circuitry 1029, and/or the arbiter 1025, may be configured to provide a technical solution to support staggered execution of at least some of the integrity-verification sweeps. For example, the staggered execution of at least some of the integrity-verification sweeps may provide a technical solution to avoid excessive power surge, e.g., during parallel access to many flip-flops.

In some demonstrative aspects, the register protection mechanism, e.g., including the integrity-verification sweep circuitry 1026, the address generation circuitry 1029, and/or the arbiter 1025, may be configured to provide a technical solution to support a scalable design for a big scale SoC, for example, based on a divide and conquer method.

In some demonstrative aspects, SoC 1000 may include one or more Locksteps (LSs) 1070 to support FuSA protection for one or more components and/or functionalities, e.g., as described below.

In some demonstrative aspects, an LS 1070 may be configured to perform multiple instances of a same functionality in parallel, for example, in order to detect one or more errors. For example, the LS 1070 may be implemented according to a double logic execute and check scheme.

In one example, an LS 1070, e.g., each LS 1070, may be selectively implemented, for example, to protect one or more functionalities and/or components, for example, where implementation of a parity protection, an integrity-verification sweep, and/or any other similar mechanism and/or protection may not be possible and/or may be complicated.

In one example, an LS 1070, e.g., each LS 1070, may be selectively implemented, for example, to protect one or more AON blocks, which may be hard to test periodically.

In some demonstrative aspects, register file 1022 may include an LS 1070.

In some demonstrative aspects, NoC 1002 may include an LS 1072.

In some demonstrative aspects, FuSA manager 1030 may include an LS 1073.

In other aspects, any other additional and/or alternative component and/or element of SoC 1000 may include an LS.

In some demonstrative aspects, FuSA manager 1030 may be configured to trigger an LS fault injection input 1076 to be provided to the one or more LSs 1070.

In some demonstrative aspects, FuSA manager 1030 may be configured to trigger the LS fault injection input 1076, for example, according to an LS periodicity.

In some demonstrative aspects, FuSA manager 1030 may be configured to trigger the LS fault injection input 1076, for example, by hardware, e.g., without software intervention.

In some demonstrative aspects, FuSA manager 1030 may be configured to propagate the LS fault injection input 1076 to the one or more LSs, for example, by hardware, e.g., without software intervention.

In some demonstrative aspects, SoC 1000 may be configured to implement the one or more LSs 1070, for example, to provide a technical solution to support a scalable design of FuSA to protect SoC 1000.

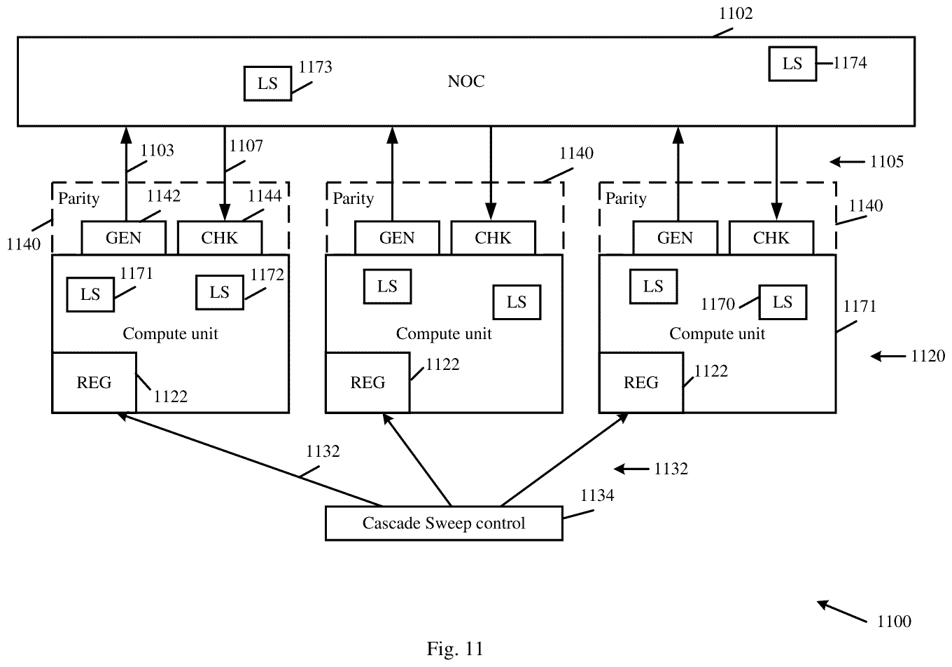

Reference is made to FIG. 11, which schematically illustrates components of a FuSA mechanism implemented by an SoC 1100. For example, SoC 1000 (FIG. 10) may include one or more elements of SoC 1100, and/or may perform one or more operations and/or functionalities of SoC 1100.

In some demonstrative aspects, as shown in FIG. 11, SoC 1100 may include a plurality of ICs 1120.

In some demonstrative aspects, as shown in FIG. 11, SoC 1100 may include at least one NoC 1102, which may be configured to communicate information between the plurality of ICs 1120.

In some demonstrative aspects, as shown in FIG. 11, SoC 1100 may include a plurality of parity circuits 1140.

In some demonstrative aspects, as shown in FIG. 11, the plurality of parity circuits 1140 may be on, e.g., arranged on, a plurality of IC-NoC paths 1105 between the plurality of ICs 1120 and the at least one NoC 1102.

In some demonstrative aspects, as shown in FIG. 11, a parity circuit 1140 on an IC-NoC path 1105 between an IC 1120 and the at least one NoC 1102 may include a parity generator 1142 and a parity checker 1144.

In some demonstrative aspects, as shown in FIG. 11, the parity generator 1142 may be configured to generate a parity value for first information 1103 provided from the IC 1120 to the at least one NoC 1102.

In some demonstrative aspects, as shown in FIG. 11, the parity checker 1144 may be configured to check a parity value of second information 1107 provided from the at least one NoC 1102 to the IC 1120.

In some demonstrative aspects, the parity checker 1144 may be configured to selectively provide, generate, output and/or send a parity-error signal, for example, based on the checking of the parity value of second information 1107, e.g., as described below.

For example, the parity checker 1144 may be configured to detect a parity error, for example, based on a comparison between the parity value of information 1107 and a calculated parity value based on the information 1107, e.g., according to the parity protocol.

In some demonstrative aspects, a FuSA manager, e.g., FuSA manager 1030 (FIG. 10), may be configured to generate the FuSA information 1012 (FIG. 10), for example, based on one or more parity-error signals from the plurality of parity circuits 1140.

In some demonstrative aspects, as shown in FIG. 11, SoC 1100 may include a plurality of register files 1122.

In some demonstrative aspects, as shown in FIG. 11, a register file 1122 of the plurality of register files 1122 may include integrity-verification sweep circuitry (not shown in FIG. 11), e.g., integrity-verification sweep circuitry 1026 (FIG. 10), which may be configured to control an integrity-verification sweep, for example, based on a trigger signal 1132.

In some demonstrative aspects, as shown in FIG. 11, SoC 1100 may include integrity-verification trigger circuitry 1134.

In some demonstrative aspects, as shown in FIG. 11, integrity-verification trigger circuitry 1134 may be configured to generate a plurality of trigger signals 1132, for example, to trigger integrity-verification sweeps by the plurality of register files 1122, for example, according to a trigger scheme.

In some demonstrative aspects, the trigger scheme may include sequential triggering, e.g., a cascaded triggering, of at least some, e.g., some or all, of the integrity-verification sweeps.

In some demonstrative aspects, FuSA manager 1030 may be configured to generate the FuSA information 1012 (FIG. 10), for example, based on parity-error signals from the plurality of register files 1122.

In some demonstrative aspects, as shown in FIG. 11, SoC 1100 may include one or more LSs 1170.

In some demonstrative aspects, as shown in FIG. 11, register file 1122 may include an LS 1171 and an LS 1172.

In some demonstrative aspects, as shown in FIG. 11, NoC 1102 may include an LS 1173 and an LS 1174.

In other aspects, any other additional and/or alternative component and/or element of SoC 1100 may include an LS.

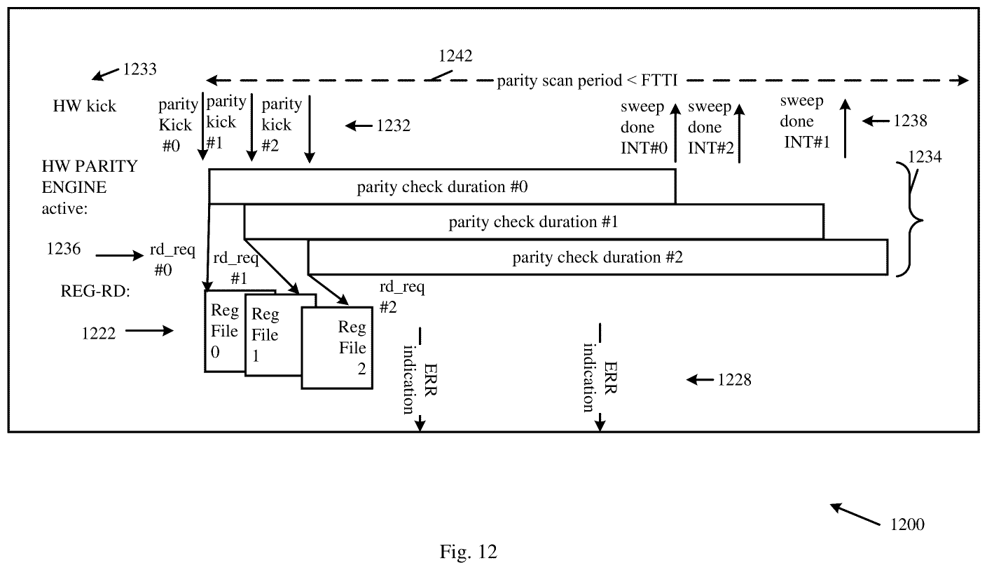

Reference is made to FIG. 12, which schematically illustrates an integrity-verification sweep scheme 1200 to implement a plurality of integrity-verification sweeps 1234 on a plurality of register files 1222, in accordance with some demonstrative aspects. For example, one or more register files of the plurality of register files 1022 (FIG. 10) may include one or more elements of plurality of register files 1222, and/or may perform one or more operations and/or functionalities of plurality of register files 1222.

In some demonstrative aspects, as shown in FIG. 12, the integrity-verification sweep scheme 1200 may include triggering a plurality of trigger signals 1232, for example, to trigger the integrity-verification sweeps 1234 by the plurality of register files 1222, for example, according to a trigger scheme.

In some demonstrative aspects, as shown in FIG. 12, the triggering of the plurality of trigger signals 1232 may be triggered by a HW kick 1233.

In one example, the HW kick 1233 may be triggered by a hardware module, which may be allowed to switch to a sleep mode, for example, after the HW kick 1233.

In some demonstrative aspects, as shown in FIG. 12, the trigger scheme may include generating the plurality of trigger signals 1232 to sequentially trigger the plurality of integrity-verification sweeps 1234.

In one example, the plurality of trigger signals 1232 may be configured to the trigger the plurality of integrity-verification sweeps 1234 in a staggered manner, for example, to avoid a current-voltage (IR) drop.

In some demonstrative aspects, as shown in FIG. 12, the plurality of integrity-verification sweeps 1234 may include a plurality of read operations 1236 to read from the plurality of register files 1222.

In some demonstrative aspects, the plurality of integrity-verification sweeps 1234 may include verifying an integrity of a register file 1222, for example, based on a parity check of the information read from the register file. For example, the parity check may include determining a calculated parity value based on the information read from the register file 1022, and comparing the calculated parity value to a parity value associated with the information read from the register file 1022.

In some demonstrative aspects, as shown in FIG. 12, the plurality of integrity-verification sweeps 1234 may include selectively providing one or more parity-error signals 1228, for example, based on the parity checks of the values in the plurality of register files 1222.

In some demonstrative aspects, as shown in FIG. 12, integrity-verification sweep scheme 1200 may include providing a plurality of sweep-complete signals 1238 to indicate completion of the integrity-verification sweeps 1234. For example, integrity-verification sweep scheme 1200 may provide a sweep-complete signal 1238, for example, when an integrity-verification sweeps 1234 is complete.

In some demonstrative aspects, as shown in FIG. 12, integrity-verification sweep scheme 1200 may include repeatedly generating the plurality of trigger signals 1232, for example, according to a sweep periodicity interval. For example, as shown in FIG. 12, the sweep periodicity interval may be shorter than an FTTI 1242.

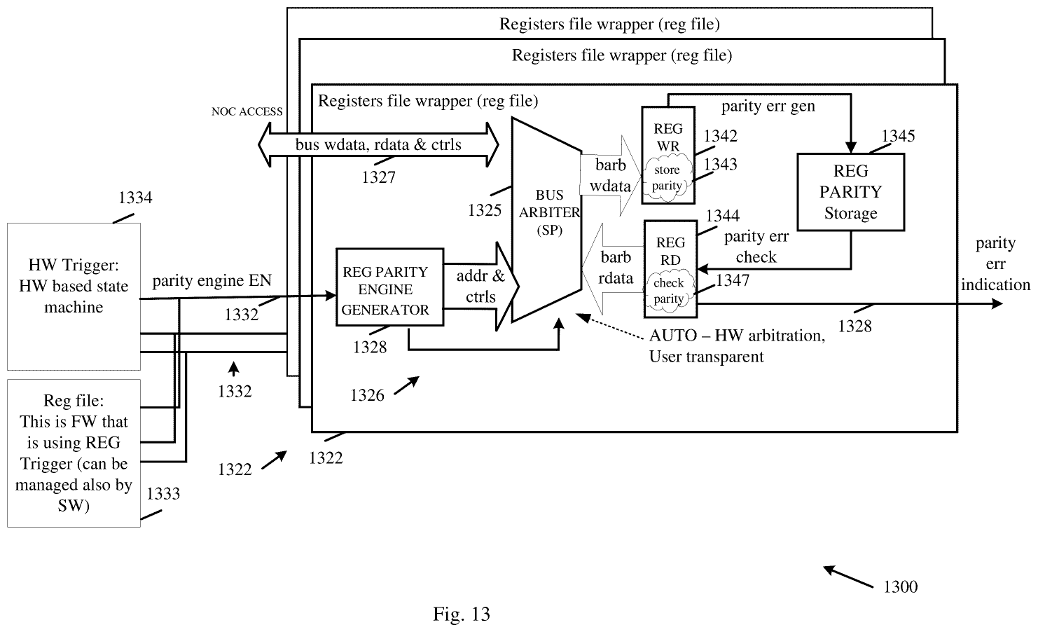

Reference is made to FIG. 13, which schematically illustrates a register file integrity verification mechanism 1300. For example, SoC 1000 (FIG. 10) may include one or more elements of integrity verification mechanism 1300, and/or may perform one or more operations and/or functionalities of integrity verification mechanism 1300.

In some demonstrative aspects, as shown in FIG. 13, integrity verification mechanism 1300 may be implemented to verify the integrity of a plurality of register files 1322. For example, the plurality of register files 1222 (FIG. 12) may include one or more elements of plurality of register files 1322, and/or may perform one or more operations and/or functionalities of plurality of register files 1322.

In some demonstrative aspects, as shown in FIG. 13, integrity verification mechanism 1300 may include integrity-verification trigger circuitry 1334, which may be configured to generate a plurality of trigger signals 1332, for example, to trigger integrity-verification sweeps by the plurality of register files 1322.

In some demonstrative aspects, as shown in FIG. 13, integrity verification mechanism 1300 may include a Firmware (FW) 1333, which may be configured to utilize the plurality of trigger signals 1332.

In some demonstrative aspects, a register file 1322 of the plurality of register files 1322 may be configured to read information (“read data” or “rdata”) from, and/or write information (“write data” or “wdata”) to, a plurality of registers 1345 of the register file 1322.

In some demonstrative aspects, as shown in FIG. 13, the register file 1322 may be configured to generate a parity value (“store parity”) 1343 for information written to a register 1345.

In some demonstrative aspects, as shown in FIG. 13, the register file 1322 may be configured to store the parity value 1343 associated with the information written to the register 1345.

In some demonstrative aspects, as shown in FIG. 13, the register file 1322 may be configured to perform a parity check 1347 for information read from the register 1345. For example, the register file 1322 may be configured to determine a calculated parity value corresponding to the information read from the register 1345, and to compare the calculated parity value to the parity value 1343 associated with the information read from the register 1345.

In some demonstrative aspects, as shown in FIG. 13, the register file 1322 may include integrity-verification sweep circuitry 1326, which may be configured to control an integrity-verification sweep, for example, based on a trigger signal 1332.

In some demonstrative aspects, the integrity-verification sweep may include reading from the plurality of registers 1345 of the register file 1322, and selectively providing a parity-error signal 1328, for example, based on parity checks of values in the plurality of registers 1345 of the register file 1322.

In some demonstrative aspects, as shown in FIG. 13, the integrity-verification sweep may include performing a parity check 1347 with respect to the information read from the register 1345, and selectively providing the parity-error signal 1328, for example, based on the parity check 1347. For example, the parity-error signal 1328 may be provided in case the parity check 1347 fails, e.g., in case the calculated parity does not match the parity value 1343 associated with the information read from the register 1345.

In some demonstrative aspects, as shown in FIG. 13, the register file 1322 may include address generation circuitry 1329, which may be configured to sequentially generate addresses of the plurality of registers 1345 in the register file 1322, for example, based on the trigger signal 1332. For example, the address generation circuitry 1329 may be configured to sequentially generate addresses of the plurality of registers 1345, which may be checked for integrity during the integrity-verification sweep. In one example, the addresses to be generated by the address generation circuitry 1329 may be predefined and/or preconfigured, for example, based on identification of selected registers to be checked for integrity.

In some demonstrative aspects, the register file 1322 may include an arbiter 1325 (also referred to as “bus arbiter” or “barb”), which may be configured to prioritize a read access and/or write access 1327 to the register file 1322 over the integrity-verification sweep.

In one example, arbiter 1325 may be configured to always give priority to read and/or write access 1327. According to this example, address generation circuitry 1329 may be configured to wait until the read and/or write access 1327 is completed, before continuing to generate addresses for the integrity-verification sweep.

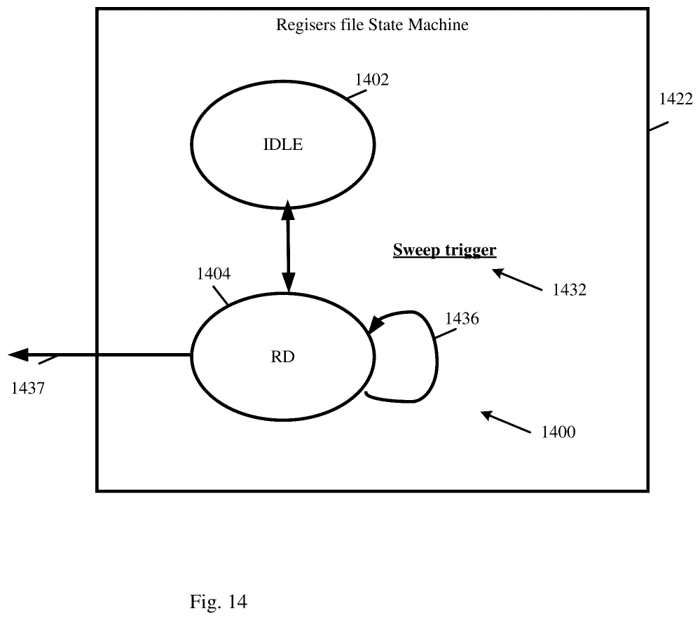

Reference is made to FIG. 14, which schematically illustrates a state diagram 1400 of an integrity-verification sweep over a register file 1422. For example, register file 1322 (FIG. 13) may include one or more elements of register file 1422, and/or may perform one or more operations and/or functionalities of register file 1422.

In one example, state diagram 1400 may include one or more states of register file 1322 (FIG. 13).

In some demonstrative aspects, as shown in FIG. 14, register file 1422 may be at an idle state 1402, for example, between integrity-verification sweeps.

In some demonstrative aspects, as shown in FIG. 14, register file 1422 may switch from the idle state 1402 to a read state 1404, for example, based on a trigger signal 1432.

In some demonstrative aspects, as shown in FIG. 14, when at the read state 1404, the register file 1422 may repeatedly (1436) generate a plurality of addresses 1437 of a plurality of registers of the register file 1422, which are to be checked for integrity.

In some demonstrative aspects, when at the read state 1404, the register file 1422 may read from the plurality of registers in the register file 1422, e.g., according to the generated addresses 1437, and may check for parity errors in the plurality of registers in the register file 1422.

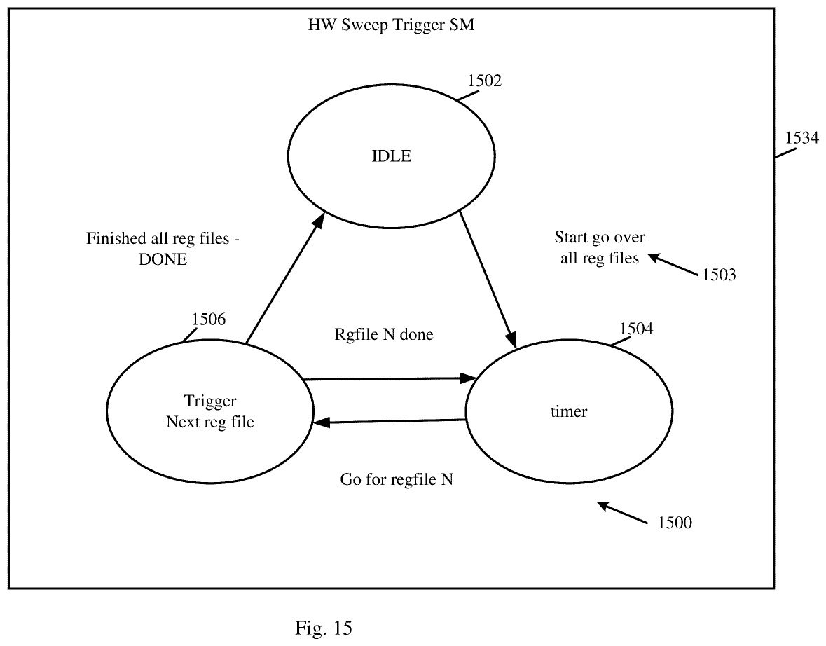

Reference is made to FIG. 15, which schematically illustrates a state diagram 1500 of integrity-verification trigger circuitry 1534. For example, integrity-verification trigger circuitry 1334 (FIG. 13) may include one or more elements of integrity-verification trigger circuitry 1534, and/or may perform one or more operations and/or functionalities of integrity-verification trigger circuitry 1534.

In one example, state diagram 1500 may include one or more states of integrity-verification trigger circuitry 1334 (FIG. 13)

In some demonstrative aspects, as shown in FIG. 15, integrity-verification trigger circuitry 1534 may be at an idle state 1502.

In some demonstrative aspects, as shown in FIG. 15, integrity-verification trigger circuitry 1534 may switch from the idle state 1502 to a timer state 1504, for example, based on a HW kick 1503, e.g., HW kick 1233 (FIG. 12), to trigger a plurality of integrity-verification sweeps of a plurality of register files.

In some demonstrative aspects, when at the timer state 1504, integrity-verification trigger circuitry 1534 may wait for a timer duration according to a sweep periodicity interval, e.g., which may be shorter than an FTTI.

In some demonstrative aspects, as shown in FIG. 15, the integrity-verification trigger circuitry 1534 may perform the integrity-verification sweeps sequentially, for example, by sequentially performing integrity-verification sweeps per each register file or per group of register files.

In some demonstrative aspects, as shown in FIG. 15, integrity-verification trigger circuitry 1534 may switch from the timer state 1504 to a triggering state 1506, for example, based on expiration of the timer duration. For example, as shown in FIG. 15, when at the triggering state 1506, integrity-verification trigger circuitry 1534 may trigger an integrity-verification sweep for a next register file of the plurality of register files.

In some demonstrative aspects, as shown in FIG. 15, integrity-verification trigger circuitry 1534 may switch back to the idle state 1502, for example, based on completion of the integrity-verification sweeps of the plurality of register files.

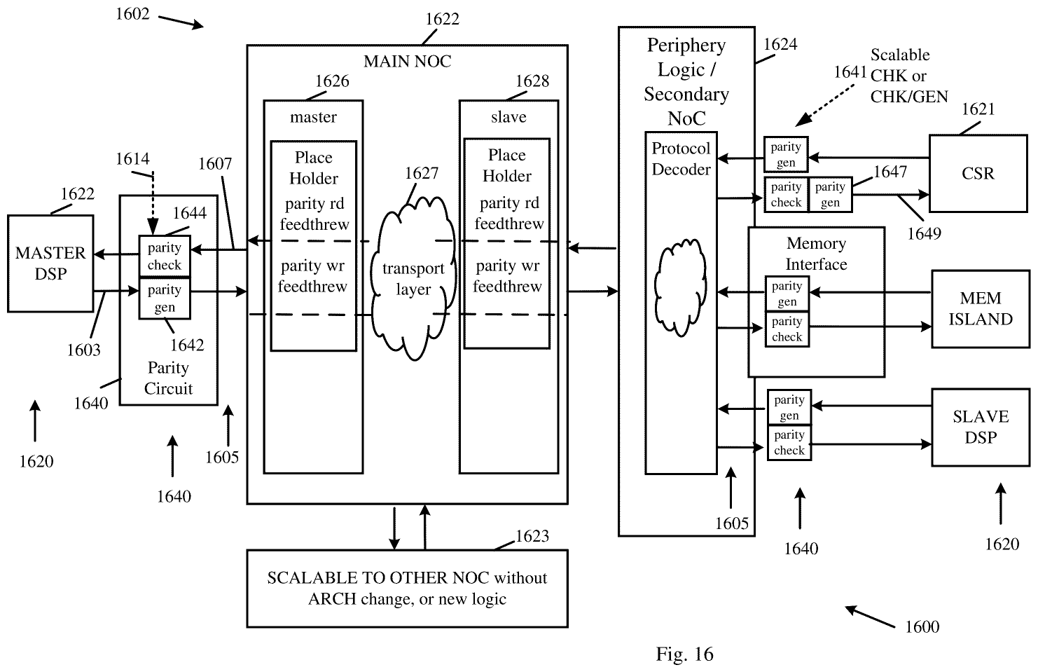

Reference is made to FIG. 16, which schematically illustrates components of a FuSA mechanism implemented by an SoC 1610. For example, SoC 1000 (FIG. 10) may include one or more elements of SoC 1610, and/or may perform one or more operations and/or functionalities of SoC 1610.

In some demonstrative aspects, as shown in FIG. 16, SoC 1600 may include a plurality of ICs 1620.

In some demonstrative aspects, as shown in FIG. 16, the plurality of ICs 1620 may include one or more DSPs, e.g., a master DSP and/or a slave DSP, one or more memory ICs, e.g., a memory island, one or more Configuration and Status Registers (CSRs), and/or any other additional and/or alternative type of IC.

In some demonstrative aspects, as shown in FIG. 16, SoC 1600 may include a NoC 1602, which may be configured to communicate information between the plurality of ICs 1620.

In some demonstrative aspects, as shown in FIG. 16, NoC 1602 may include a main NoC 1622 and/or a secondary NoC 1624, e.g., a periphery logic NoC.

In some demonstrative aspects, as shown in FIG. 16, main NoC 1622 may include a master interface 1626 and a slave interface 1628.

In some demonstrative aspects, as shown in FIG. 16, master interface 1626 may be configured to interface with one or more ICs 1620.

In some demonstrative aspects, as shown in FIG. 16, slave interface 1628 may be configured to interface with secondary NoC 1624.

In some demonstrative aspects, as shown in FIG. 16, main NoC 1622 may include a transport layer 1627 between the master interface 1626 and the slave interface 1628.

In some demonstrative aspects, as shown in FIG. 16, NoC 1602 may include a scaling interface 1623, for example, to support scaling of NoC 1602 to one or more other NoCs, for example, without an architecture change and/or new logic.

In some demonstrative aspects, as shown in FIG. 16, SoC 1600 may include a plurality of parity circuits 1640.

In some demonstrative aspects, as shown in FIG. 16, the plurality of parity circuits 1640 may be on, e.g., arranged on, a plurality of IC-NoC paths 1605 between the plurality of ICs 1620 and the NoC 1602.

In some demonstrative aspects, as shown in FIG. 16, a parity circuit 1640 on an IC-NoC path 1605 between an IC 1622 and the NoC 1602 may include a parity generator 1642 and a parity checker 1644.

In some demonstrative aspects, as shown in FIG. 16, the parity generator 1642 may be configured to generate a first parity value for first information 1603 provided from the IC 1622 to the NoC 1602.

In some demonstrative aspects, as shown in FIG. 16, the parity checker 1644 may be configured to check a second parity value of second information 1607 provided from the NoC 1602 to the IC 1622.

In some demonstrative aspects, the parity checker 1644 may be configured to selectively provide, generate, output and/or send a parity-error signal, for example, based on the checking of the parity value of second information 1607, e.g., as described below.

For example, the parity checker 1644 may be configured to detect a parity error, for example, based on a comparison between the parity value of information 1607 and a calculated parity value based on the information 1607, e.g., according to a parity protocol.

In some demonstrative aspects, as shown in FIG. 16, a parity circuit 1641 may include an additional parity generator 1647, which may be configured to generate a parity value for information 1649 provided from the secondary NoC 1624 to an IC 1621.

In some demonstrative aspects, a FuSA manager, e.g., FuSA manager 1030 (FIG. 10), may be configured to generate the FuSA information 1012 (FIG. 10), for example, based on one or more parity-error signals from the plurality of parity circuits 1640.

In some demonstrative aspects, the FuSA manager, e.g., FuSA manager 1030 (FIG. 10), may be configured to trigger a fault injection input 1614 to be provided to verify a functionality of a parity checker 1644 and/or a party generator 1642.

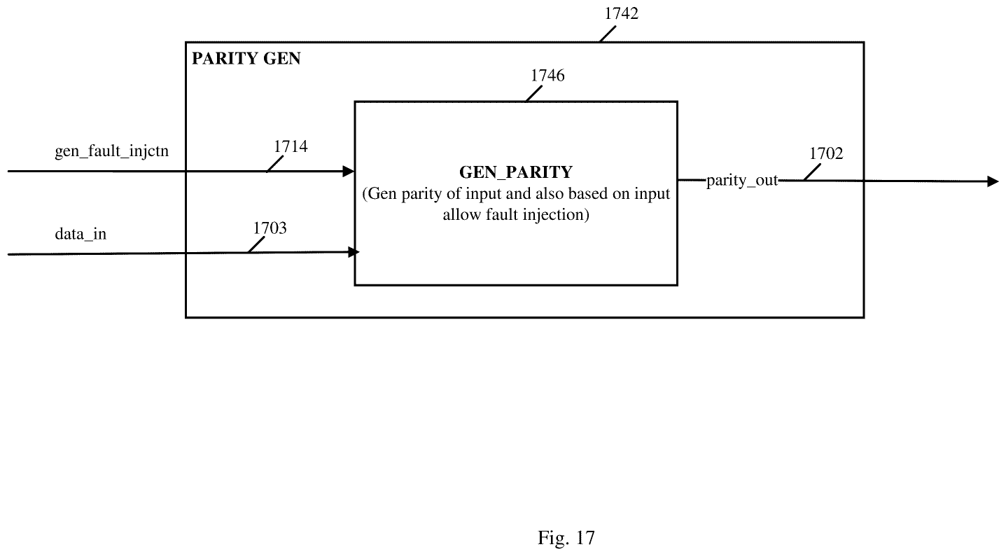

Reference is made to FIG. 17, which schematically illustrates a parity generator 1742, in accordance with some demonstrative aspects. For example, parity generator 1042 (FIG. 10), parity generator 1142 (FIG. 11), and/or 1642 (FIG. 16) may include one or more elements of parity generator 1742, and/or may perform one or more operations and/or functionalities of parity generator 1742.

In some demonstrative aspects, as shown in FIG. 17, the parity generator 1742 may include a parity value generator 1746, which may be configured to generate a parity value 1702 based on input information 1703.

In one example, the input information 1703 may include information provided from an IC to a NoC. For example, the information 1703 may include information 1603 (FIG. 16), which may be provided from the IC 1622 (FIG. 16) to the NoC 1602 (FIG. 16).

In some demonstrative aspects, as shown in FIG. 17, the parity generator 1742 may be configured to generate the parity value 1702, for example, based on a fault injection input 1714. For example, the functionality of the parity generator 1742 may be verified, for example, based on comparison between the parity value 1702, which is generated by the parity generator 1742 based on the fault injection input 1714, and a predetermined expected parity value corresponding to the fault injection input 1714.

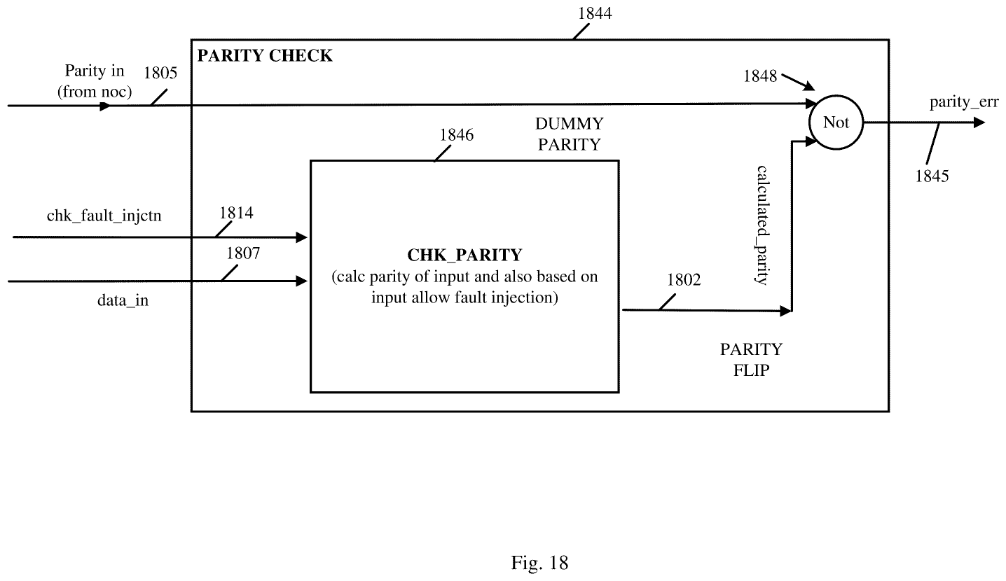

Reference is made to FIG. 18, which schematically illustrates a parity checker 1844, in accordance with some demonstrative aspects. For example, parity checker 1044 (FIG. 10), parity checker 1144 (FIG. 11), and/or parity checker 1644 (FIG. 16) may include one or more elements of parity checker 1844, and/or may perform one or more operations and/or functionalities of parity checker 1844.

In some demonstrative aspects, as shown in FIG. 18, the parity checker 1844 may include a parity calculator 1846, which may be configured to generate a calculated parity value 1802 based on input information 1807.

In one example, the input information 1807 may include information provided from a NoC to an IC. For example, the input information 1807 may include information 1607 (FIG. 16), which may be provided from the NoC 1602 (FIG. 16) to the IC 1622 (FIG. 16).

In some demonstrative aspects, as shown in FIG. 18, the parity checker 1844 may include a comparator 1848, which may be configured to compare between the calculated parity value 1802 and a parity value 1805 for the input information 1807 from the NoC. For example, the party value 1805 may be appended to and/or associated with the input information 1807.

In some demonstrative aspects, as shown in FIG. 18, the parity checker 1844 may be configured to provide, generate, output and/or send a parity-error signal 1845, for example, based on a determination that the calculated parity value 1802 for the information 1807 is different from the parity value 1805.

For example, as shown in FIG. 18, comparator 1848 may include a logical “NOT” comparator, e.g., “!=”, to provide parity-error signal 1845 based, for example, on a logical “NOT” applied to the calculated parity value 1802 and the parity value 1805 for the input information 1807.

In some demonstrative aspects, as shown in FIG. 18, the parity checker 1844 may be configured to determine the calculated parity value 1802, for example, based on a fault injection input 1814. For example, the functionality of the parity checker 1844 may be verified based on the calculated parity value 1802, which is based on the fault injection input 1814.

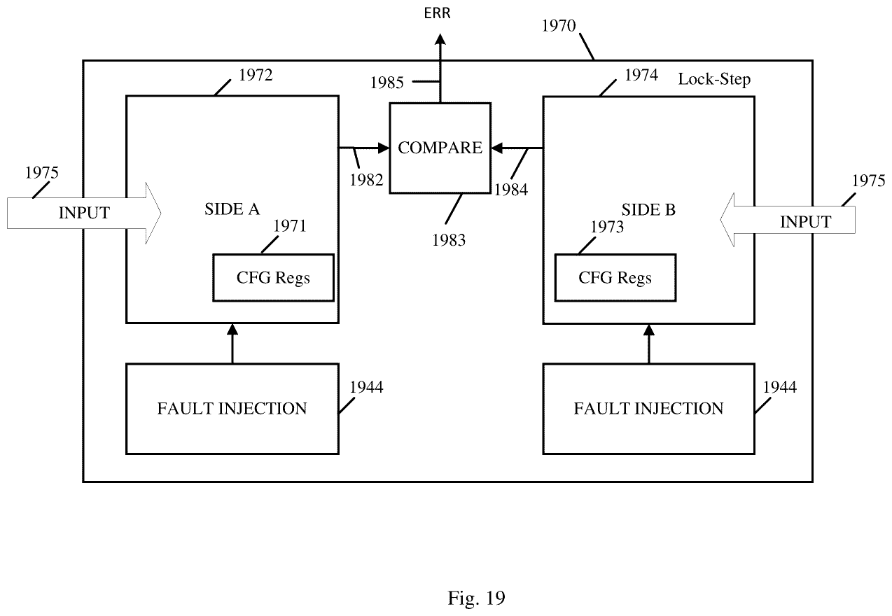

Reference is made to FIG. 19, which schematically illustrates LS circuitry 1970, in accordance with some demonstrative aspects. For example, an LS 1070 (FIG. 10) may include one or more elements of LS circuitry 1970, and/or may perform one or more operations and/or functionalities of LS circuitry 1970.

In some demonstrative aspects, as shown in FIG. 19, LS circuitry 1970 may include a first circuit 1972 and a second circuit 1974.

In some demonstrative aspects, the first circuit 1972 and the second circuit 1974 may be configured to perform the same operation in parallel on a same input 1975.

For example, the first circuit 1972 and the second circuit 1974 may be implemented by two identical circuits.

In some demonstrative aspects, as shown in FIG. 19, the first circuit 1972 may include one or more configuration registers 1971.

In some demonstrative aspects, as shown in FIG. 19, the second circuit 1974 may include one or more configuration registers 1973, e.g., identical to the one or more configuration registers 1971.

In other aspects, the first circuit 1972 and/or the second circuit 1974 may include any other additional and/or alternative registers and/or hardware.

In some demonstrative aspects, as shown in FIG. 19, LS circuitry 1970 may include a comparator 1983, which may be configured to compare between an output 1982 from the first circuit 1972 and an output 1984 from the second circuit 1974.

In some demonstrative aspects, as shown in FIG. 19, LS circuitry 1970 may be configured to provide, generate, output and/or send an LS-error signal 1985, for example, based on a determination that the output 1982 from the first circuit 1972 is different from the output 1984 from the second circuit 1974.

In some demonstrative aspects, as shown in FIG. 19, LS circuitry 1970 may be configured to compare between the output 1982 from the first circuit 1972 and the output 1984 from the second circuit 1974, for example, based on a fault injection input 1944.

In some demonstrative aspects, a FuSA manager, e.g., FuSA manager 1030 (FIG. 10), may be configured to generate the FuSA information 1012 (FIG. 10), for example, based on LS-error signal 1985 from the LS circuitry 1970.

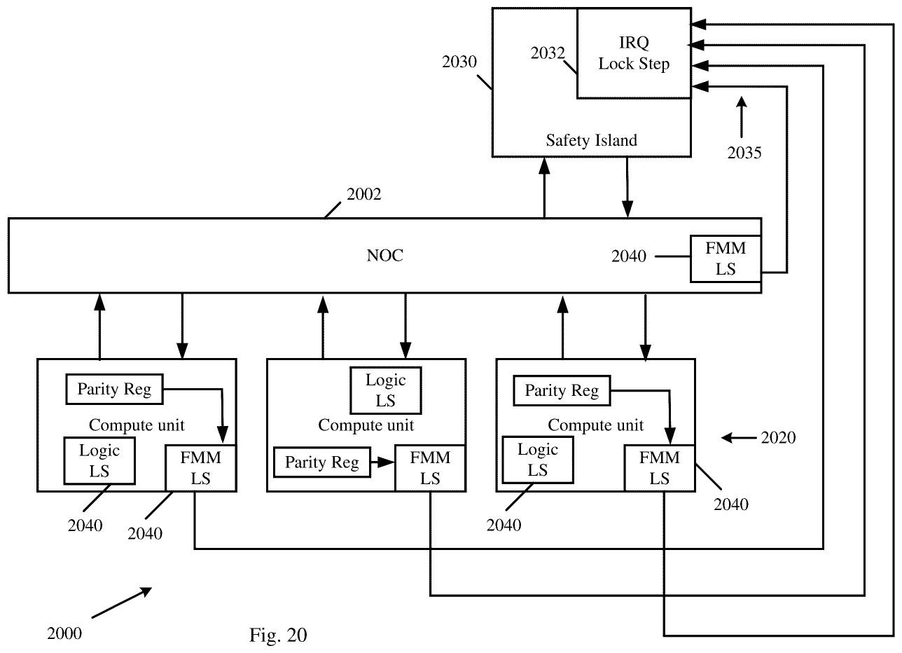

Reference is made to FIG. 20, which schematically illustrates components of a FuSA mechanism implemented by an SoC 2010. For example, SoC 1000 (FIG. 10) may include one or more elements of SoC 2010, and/or may perform one or more operations and/or functionalities of SoC 2010.

In some demonstrative aspects, as shown in FIG. 20, SoC 2000 may include a plurality of ICs 2020.

In some demonstrative aspects, as shown in FIG. 20, SoC 2000 may include a NoC 2002, which may be configured to communicate information between the plurality of ICs 2020.

In some demonstrative aspects, as shown in FIG. 20, SoC 2000 may include a plurality of LSs 2040.

In some demonstrative aspects, as shown in FIG. 20, the plurality of LSs 2040 may include one or more Fault Manager Module (FMM) LSs, one or more Logic LSs, and/or any other additional and/or alternative type of LS.

In some demonstrative aspects, as shown in FIG. 20, the plurality of LSs 2040 may include one or more LSs 2040, e.g., Logic LSs, implemented in the plurality of ICs 2020.

In some demonstrative aspects, as shown in FIG. 20, the plurality of LSs 2040 may include one or more LSs 2040, e.g., FMM LSs, implemented in the NoC 2002.

In some demonstrative aspects, as shown in FIG. 20, SoC 2000 may include a FuSA manager 2030, e.g., implemented as a Safety Island, which may be configured to manage FuSA of the SoC 2000.

In some demonstrative aspects, as shown in FIG. 20, FuSA manager 2030 may include an LS manager 2032, e.g., implemented by an Interrupt Request (IRQ) controller, which may be configured to process a plurality of LS-error signals 2035 from the plurality of LSs 2040.

In some demonstrative aspects, FuSA manager 1030 (FIG. 10) may be configured perform one or more operations and/or functionalities of FuSA manager 2030, for example, to generate the FuSA information 1012 (FIG. 10), for example, based on the plurality of LS-error signals 2035 from the plurality of LSs 2040.

In some demonstrative aspects, as shown in FIG. 20, one or more LS faults, e.g., all LS faults, for SoC 2000 may be aggregated by LS manager 2032, e.g., via LS-error signals 2035, for example, using lockstep mechanisms.

In some demonstrative aspects, LS manager 2032 may be secured from faults, for example, by a lockstep mechanism.

In some demonstrative aspects, LS-error signals 2035 may be wired by hardware to the LS manager 2032 in the safety island.

In some demonstrative aspects, LS manager 2032 may be auto managed by HW, for example, even without the use of substantially any SW management.

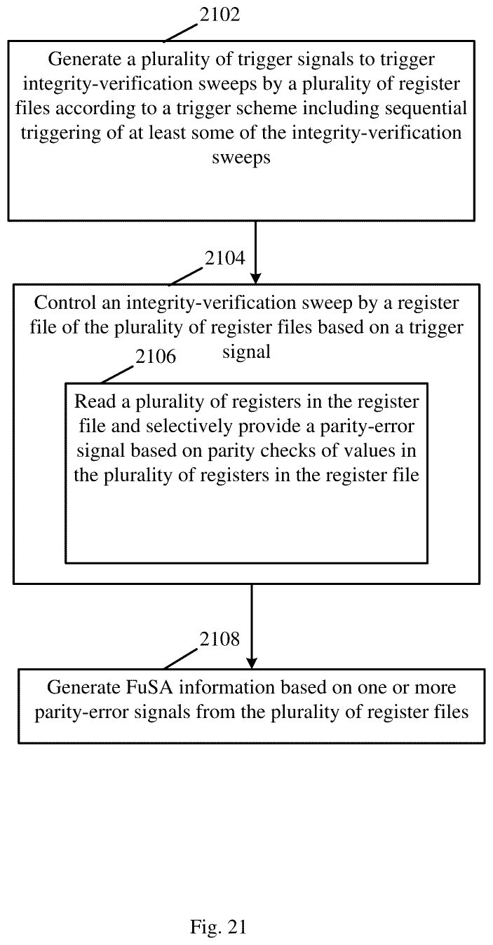

Reference is made to FIG. 21, which schematically illustrates a method of FuSA based on register file integrity verification. For example, one or more of the operations of the method of FIG. 21 may be performed by a FuSA manager, e.g., FuSA manager 1030 (FIG. 10); integrity-verification trigger circuitry, e.g., integrity-verification trigger circuitry 1034 (FIG. 10), and/or integrity-verification sweep circuitry, e.g., integrity-verification sweep circuitry 1026 (FIG. 10).

In some demonstrative aspects, as indicated at block 2102, the method may include generating a plurality of trigger signals to trigger integrity-verification sweeps by a plurality of register files according to a trigger scheme including sequential triggering of at least some of the integrity-verification sweeps. For example, integrity-verification trigger circuitry 1034 (FIG. 10) may be configured to trigger the integrity-verification sweeps by the plurality of register files 1022 (FIG. 10) according to the trigger scheme including the sequential triggering of at least some of the integrity-verification sweeps, e.g., as described above.

In some demonstrative aspects, as indicated at block 2104, the method may include controlling an integrity-verification sweep by a register file of the plurality of register files based on a trigger signal. For example, integrity-verification sweep circuitry 1026 (FIG. 10) may be configured to control the integrity-verification sweep by the register file 1022 (FIG. 10), for example, based on trigger signal 1032 (FIG. 10), e.g., as described above.

In some demonstrative aspects, as indicated at block 2106, controlling the integrity-verification sweep by the register file may include reading a plurality of registers and selectively providing a parity-error signal, for example, based on parity checks of values in the plurality of registers in the register file. For example, integrity-verification sweep circuitry 1026 (FIG. 10) may be configured to control reading the plurality of registers 1024 (FIG. 10) and selectively providing the parity-error signal 1028 (FIG. 10), for example, based on parity checks of the values in the plurality of registers 1024 (FIG. 10) in the register file 1022 (FIG. 10), e.g., as described above.

In some demonstrative aspects, as indicated at block 2108, the method may include generating FuSA information, for example, based on parity-error signals from the plurality of register files. For example, FuSA manager 1030 (FIG. 10) may generate FuSA information 1012 (FIG. 10), for example, based on the parity-error signals 1028 (FIG. 10) from the plurality of register files 1022 (FIG. 10), e.g., as described above.

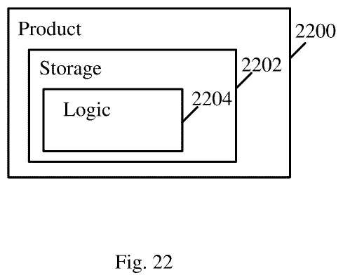

Reference is made to FIG. 22, which schematically illustrates a product of manufacture 2200, in accordance with some demonstrative aspects. Product 2200 may include one or more tangible computer-readable (“machine-readable”) non-transitory storage media 2202, which may include computer-executable instructions, e.g., implemented by logic 2204, operable to, when executed by at least one computer processor, enable the at least one computer processor to implement one or more operations and/or functionalities described with reference to any of the FIGS. 1-21, and/or one or more operations described herein. The phrases “non-transitory machine-readable medium” and “computer-readable non-transitory storage media” may be directed to include all machine and/or computer readable media, with the sole exception being a transitory propagating signal.

In some demonstrative aspects, product 2200 and/or machine-readable storage media 2202 may include one or more types of computer-readable storage media capable of storing data, including volatile memory, non-volatile memory, removable or non-removable memory, erasable or non-erasable memory, writeable or re-writeable memory, and the like. For example, machine-readable storage media 2202 may include, RAM, DRAM, Double-Data-Rate DRAM (DDR-DRAM), SDRAM, static RAM (SRAM), ROM, programmable ROM (PROM), erasable programmable ROM (EPROM), electrically erasable programmable ROM (EEPROM), flash memory (e.g., NOR or NAND flash memory), content addressable memory (CAM), polymer memory, phase-change memory, ferroelectric memory, silicon-oxide-nitride-oxide-silicon (SONOS) memory, a disk, a hard drive, and the like. The computer-readable storage media may include any suitable media involved with downloading or transferring a computer program from a remote computer to a requesting computer carried by data signals embodied in a carrier wave or other propagation medium through a communication link, e.g., a modem, radio or network connection.

In some demonstrative aspects, logic 2204 may include instructions, data, and/or code, which, if executed by a machine, may cause the machine to perform a method, process and/or operations as described herein. The machine may include, for example, any suitable processing platform, computing platform, computing device, processing device, computing system, processing system, computer, processor, or the like, and may be implemented using any suitable combination of hardware, software, firmware, and the like.

In some demonstrative aspects, logic 2204 may include, or may be implemented as, software, a software module, an application, a program, a subroutine, instructions, an instruction set, computing code, words, values, symbols, and the like. The instructions may include any suitable type of code, such as source code, compiled code, interpreted code, executable code, static code, dynamic code, and the like. The instructions may be implemented according to a predefined computer language, manner or syntax, for instructing a processor to perform a certain function. The instructions may be implemented using any suitable high-level, low-level, object-oriented, visual, compiled and/or interpreted programming language, machine code, and the like.

### EXAMPLES

The following examples pertain to further aspects.

Example 1 includes an apparatus comprising a System on Chip (SoC) comprising a plurality of Integrated Circuits (ICs); at least one Network on Chip (NoC) to communicate information between the plurality of ICs; a plurality of parity circuits on, e.g., arranged on, a plurality of IC-NoC paths between the plurality of ICs and the at least one NoC, the plurality of parity circuits configured according to a same parity protocol, wherein a parity circuit on an IC-NoC path between an IC and the at least one NoC comprises a parity generator and a parity checker, the parity generator configured to generate a first parity value for first information provided from the IC to the at least one NoC, the parity checker configured to selectively provide a parity-error signal based on a parity check of a second parity value of second information provided from the at least one NoC to the IC; and a Functional Safety (FuSA) manager configured to generate FuSA information based on one or more parity-error signals from the plurality of parity circuits.

Example 2 includes the subject matter of Example 1, and optionally, wherein the parity protocol is independent of a configuration of the at least one NoC.

Example 3 includes the subject matter of Example 1 or 2, and optionally, wherein the parity protocol is independent of an information format of the information communicated between the plurality of ICs.

Example 4 includes the subject matter of any one of Examples 1-3, and optionally, wherein the FuSA manager is configured to trigger a fault injection input to be provided to one or more of the plurality of parity circuits.

Example 5 includes the subject matter of Example 4, and optionally, wherein the FuSA manager is configured to trigger the fault injection input at an Always On (AON) state of the at least one NoC.

Example 6 includes the subject matter of any one of Examples 1-5, and optionally, wherein the parity circuit is configured to apply the parity protocol to data communicated over the IC-NoC path.

Example 7 includes the subject matter of any one of Examples 1-6, and optionally, wherein the parity circuit is configured to apply the parity protocol to address information of data packets communicated over the IC-NoC path.

Example 8 includes the subject matter of any one of Examples 1-7, and optionally, wherein the plurality of parity circuits are on, e.g., arranged on, at least 80% of all IC-NoC paths having an active average utilization of at least 5%.

Example 9 includes the subject matter of any one of Examples 1-8, and optionally, wherein the plurality of parity circuits are on, e.g., arranged on, at least 90% of all IC-NoC paths having an active average utilization of at least 5%.

Example 10 includes the subject matter of any one of Examples 1-9, and optionally, wherein the plurality of parity circuits are on, e.g., arranged on, at least 80% of all IC-NoC paths having an active average utilization of at least 10%.

Example 11 includes the subject matter of any one of Examples 1-10, and optionally, wherein the plurality of parity circuits are on, e.g., arranged on, at least 90% of all IC-NoC paths having an active average utilization of at least 10%.

Example 12 includes the subject matter of any one of Examples 1-11, and optionally, wherein the plurality of parity circuits are on, e.g., arranged on, at least 50% of all IC-NoC paths between the plurality of ICs and the at least one NoC.

Example 13 includes the subject matter of any one of Examples 1-12, and optionally, wherein the plurality of parity circuits are on, e.g., arranged on, at least 70% of all IC-NoC paths between the plurality of ICs and the at least one NoC.

Example 14 includes the subject matter of any one of Examples 1-13, and optionally, wherein the plurality of parity circuits are on, e.g., arranged on, at least 80% of all IC-NoC paths between the plurality of ICs and the at least one NoC.

Example 15 includes the subject matter of any one of Examples 1-14, and optionally, wherein the plurality of parity circuits are on, e.g., arranged on, at least 90% of all IC-NoC paths between the plurality of ICs and the at least one NoC.

Example 16 includes the subject matter of any one of Examples 1-15, and optionally, wherein the plurality of ICs comprises at least one of a processor IC, or a memory IC.

Example 17 includes the subject matter of any one of Examples 1-16, and optionally, comprising a radar device, the radar device comprising a plurality of Transmit (Tx) antennas to transmit radar Tx signals, and a plurality of Receive (Rx) antennas to receive radar Rx signals based on the radar Tx signals, wherein the plurality of ICs comprises one or more ICs to handle information corresponding to at least one of the radar Tx signals or the radar Rx signals.

Example 18 includes the subject matter of Example 17, and optionally, comprising a vehicle, the vehicle comprising the radar device, and a system controller to control one or more systems of the vehicle based on radar information provided by the radar device.

Example 19 includes an apparatus comprising a System on Chip (SoC) comprising a plurality of register files, wherein a register file of the plurality of register files comprises integrity-verification sweep circuitry configured to control an integrity-verification sweep based on a trigger signal, the integrity-verification sweep comprising reading a plurality of registers in the register file, and selectively providing a parity-error signal based on parity checks of values in the plurality of registers; integrity-verification trigger circuitry configured to generate a plurality of trigger signals to trigger integrity-verification sweeps by the plurality of register files according to a trigger scheme comprising sequential triggering of at least some of the integrity-verification sweeps; and a Functional Safety (FuSA) manager configured to generate FuSA information based on parity-error signals from the plurality of register files.

Example 20 includes the subject matter of Example 19, and optionally, wherein the integrity-verification trigger circuitry is configured to generate the plurality of trigger signals independent from read or write accesses to the plurality of register files.

Example 21 includes the subject matter of Example 19 or 20, and optionally, wherein the register file comprises address generation circuitry configured to sequentially generate addresses of the plurality of registers in the register file based on the trigger signal.

Example 22 includes the subject matter of any one of Examples 19-21, and optionally, wherein the register file comprises an arbiter configured to prioritize a read or write access to the register file over the integrity-verification sweep.

Example 23 includes the subject matter of any one of Examples 19-22, and optionally, wherein the integrity-verification trigger circuitry is configured to repeat generating the plurality of trigger signals according to a sweep periodicity interval.

Example 24 includes the subject matter of Example 23, and optionally, wherein the sweep periodicity interval is shorter than a Fault Tolerant Time Interval (FTTI) for the SoC.

Example 25 includes the subject matter of any one of Examples 19-24, and optionally, wherein the trigger scheme is configured to trigger staggered execution of the at least some of the integrity-verification sweeps.

Example 26 includes the subject matter of any one of Examples 19-25, and optionally, wherein the trigger scheme comprises sequential triggering of at least 50% of the integrity-verification sweeps.

Example 27 includes the subject matter of any one of Examples 19-26, and optionally, wherein the trigger scheme comprises sequential triggering of at least 60% of the integrity-verification sweeps.

Example 28 includes the subject matter of any one of Examples 19-27, and optionally, wherein the trigger scheme comprises sequential triggering of at least 70% of the integrity-verification sweeps.

Example 29 includes the subject matter of any one of Examples 19-28, and optionally, wherein the trigger scheme comprises sequential triggering of at least 80% of the integrity-verification sweeps.

Example 30 includes the subject matter of any one of Examples 19-29, and optionally, wherein the plurality of register files comprises a plurality of static register files.

Example 31 includes the subject matter of any one of Examples 19-30, and optionally, wherein the plurality of register files comprises a plurality of configuration register files.

Example 32 includes the subject matter of any one of Examples 19-31, and optionally, comprising a radar device, the radar device comprising a plurality of Transmit (Tx) antennas to transmit radar Tx signals, and a plurality of Receive (Rx) antennas to receive radar Rx signals based on the radar Tx signals, wherein the SoC is configured to handle information corresponding to at least one of the radar Tx signals or the radar Rx signals.

Example 33 includes the subject matter of Example 32, and optionally, comprising a vehicle, the vehicle comprising the radar device, and a system controller to control one or more systems of the vehicle based on radar information provided by the radar device.

Example 34 includes a System on Chip (SoC) according to any of Examples 1-33.

Example 35 includes a device comprising a System on Chip (SoC) according to any of Examples 1-33.

Example 36 includes a radar device comprising a System on Chip (SoC) according to any of Examples 1-33.

Example 37 includes a vehicle comprising a System on Chip (SoC) according to any of Examples 1-33.

Example 38 includes a method of System on Chip (SoC) Functional Safety (FuSa) including any of the described operations of any of Examples 1-33.

Example 39 includes an apparatus comprising means for System on Chip (SoC) Functional Safety (FuSa) according to any of Examples 1-33.

Example 40 includes a product comprising one or more tangible computer-readable non-transitory storage media comprising instructions operable to, when executed by at least one processor, enable the at least one processor to cause operations of System on Chip (SoC) Functional Safety (FuSa) according to any of Examples 1-33.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the disclosure.

What is claimed is:

1. An apparatus comprising:
a System on Chip (SoC) comprising:
a plurality of Integrated Circuits (ICs);
at least one Network on Chip (NoC) to communicate information between the plurality of ICs;
a plurality of parity circuits on a plurality of IC-NoC paths between the plurality of ICs and the at least one NoC, the plurality of parity circuits configured according to a same parity protocol, wherein a parity circuit on an IC-NoC path between an IC and the at least one NoC comprises a parity generator and a parity checker, the parity generator configured to generate a first parity value for first information provided from the IC to the at least one NoC, the parity checker configured to selectively provide a parity-error signal based on a parity check of a second parity value of second information provided from the at least one NoC to the IC; and
a Functional Safety (FuSA) manager configured to generate FuSA information based on one or more parity-error signals from the plurality of parity circuits.

2. The apparatus of claim 1, wherein the parity protocol is independent of a configuration of the at least one NoC.

3. The apparatus of claim 1, wherein the parity protocol is independent of an information format of the information communicated between the plurality of ICs.

4. The apparatus of claim 1, wherein the FuSA manager is configured to trigger a fault injection input to be provided to one or more of the plurality of parity circuits.

5. The apparatus of claim 4, wherein the FuSA manager is configured to trigger the fault injection input at an Always On (AON) state of the at least one NoC.

6. The apparatus of claim 1, wherein the parity circuit is configured to apply the parity protocol to data communicated over the IC-NoC path.

7. The apparatus of claim 1, wherein the parity circuit is configured to apply the parity protocol to address information of data packets communicated over the IC-NoC path.

8. The apparatus of claim 1, wherein the plurality of parity circuits are on at least 80% of all IC-NoC paths having an active average utilization of at least 5%.

9. The apparatus of claim 1, wherein the plurality of parity circuits are on at least 80% of all IC-NoC paths having an active average utilization of at least 10%.

10. The apparatus of claim 1, wherein the plurality of parity circuits are on at least 50% of all IC-NoC paths between the plurality of ICs and the at least one NoC.

11. The apparatus of claim 1, wherein the plurality of ICs comprises at least one of a processor IC, or a memory IC.

12. The apparatus of claim 1 comprising a radar device, the radar device comprising a plurality of Transmit (Tx) antennas to transmit radar Tx signals, and a plurality of Receive (Rx) antennas to receive radar Rx signals based on the radar Tx signals, wherein the plurality of ICs comprises one or more ICs to handle information corresponding to at least one of the radar Tx signals or the radar Rx signals.

13. The apparatus of claim 12 comprising a vehicle, the vehicle comprising the radar device, and a system controller to control one or more systems of the vehicle based on radar information provided by the radar device.

14. An apparatus comprising:
a System on Chip (SoC) comprising:
a plurality of register files, wherein a register file of the plurality of register files comprises integrity-verification sweep circuitry configured to control an integrity-verification sweep based on a trigger signal, the integrity-verification sweep comprising reading a plurality of registers in the register file, and selectively providing a parity-error signal based on parity checks of values in the plurality of registers;
integrity-verification trigger circuitry configured to generate a plurality of trigger signals to trigger integrity-verification sweeps by the plurality of register files according to a trigger scheme comprising sequential triggering of at least some of the integrity-verification sweeps; and
a Functional Safety (FuSA) manager configured to generate FuSA information based on parity-error signals from the plurality of register files.

15. The apparatus of claim 14, wherein the integrity-verification trigger circuitry is configured to generate the plurality of trigger signals independent from read or write accesses to the plurality of register files.

16. The apparatus of claim 14, wherein the register file comprises address generation circuitry configured to sequentially generate addresses of the plurality of registers in the register file based on the trigger signal.

17. The apparatus of claim 14, wherein the register file comprises an arbiter configured to prioritize a read or write access to the register file over the integrity-verification sweep.

18. The apparatus of claim 14, wherein the integrity-verification trigger circuitry is configured to repeat generating the plurality of trigger signals according to a sweep periodicity interval.

19. The apparatus of claim 18, wherein the sweep periodicity interval is shorter than a Fault Tolerant Time Interval (FTTI) for the SoC.

20. The apparatus of claim 14, wherein the trigger scheme is configured to trigger staggered execution of the at least some of the integrity-verification sweeps.

21. The apparatus of claim 14, wherein the trigger scheme comprises sequential triggering of at least 50% of the integrity-verification sweeps.

22. The apparatus of claim 14, wherein the plurality of register files comprises at least one of a plurality of static register files, or a plurality of configuration register files.

23. The apparatus of claim 14 comprising a radar device, the radar device comprising a plurality of Transmit (Tx) antennas to transmit radar Tx signals, and a plurality of Receive (Rx) antennas to receive radar Rx signals based on the radar Tx signals, wherein the SoC is configured to handle information corresponding to at least one of the radar Tx signals or the radar Rx signals.
